(19) United States
(12) Patent Application Publication
(10) Pub. No.: US 2025/0072217 A1
(43) Pub. Date: Feb. 27, 2025

(54) DISPLAY DEVICE AND OPTICAL DEVICE

(71) Applicant: Samsung Display Co., LTD., Yongin-si (KR)

(72) Inventors: Ji Hye LEE, Yongin-si (KR); Jin Seon KWAK, Yongin-si (KR); Kyung Bae KIM, Yongin-si (KR)

(21) Appl. No.: 18/793,582

(22) Filed: Aug. 2, 2024

(30) Foreign Application Priority Data
Aug. 21, 2023 (KR) 10-2023-0108915

(51) Int. Cl. H10K 59/121; G09G 3/3233; H10K 59/131

(52) U.S. Cl. CPC H10K 59/1213; H10K 59/131; G09G 3/3233; G09G 2300/0426; G09G 2300/0819; G09G 2300/0852; G09G 2300/0861; G09G 2330/08

(57) ABSTRACT

The present disclosure relates to a display device, and more particularly to a display device capable of repairing transistors and an optical device including the same. According to one or more embodiments of the present disclosure, a display device including: a main pixel including a light emitting element, and a main transistor; and an auxiliary pixel adjacent to the main pixel, the auxiliary pixel including an auxiliary transistor having same characteristics as the main transistor.

### CROSS-REFERENCE TO RELATED APPLICATION

The present application claims priority to and the benefit of Korean Patent Application No. 10-2023-0108915, filed on Aug. 21, 2023, in the Korean Intellectual Property Office, the entire disclosure of which is incorporated by reference herein.

### BACKGROUND

### 1. Field

The present disclosure relates to a display device, and more particularly to a display device capable of repairing transistors and an optical device including the same.

### 2. Description of the Related Art

A head mounted display (HMD) is an image display device that is worn on a user's head in the form of glasses or a helmet and focuses on a distance close to the user's eyes. The head mounted display may realize virtual reality (VR) or augmented reality (AR).

The head mounted display enlarges and displays an image displayed on a small display device using a plurality of lenses. Therefore, a display device applied to the head mounted display needs to provide a high-resolution image, for example, an image having a resolution of 3000 pixels per inch (PPI) or higher. To this end, organic light emitting diode on silicon (OLEDoS), which is a high-resolution, small-sized organic light emitting display device 10, is used as the display device applied to the head mounted display. The OLEDoS is a device that displays an image by disposing an organic light emitting diode (OLED) on a semiconductor wafer substrate on which a complementary metal oxide semiconductor (CMOS) is disposed.

### SUMMARY

Aspects and features of embodiments of the present disclosure provide a display device capable of repairing transistors and an optical device including the same.

According to one or more embodiments of the present disclosure, a display device including: a main pixel including a light emitting element, and a main transistor; and an auxiliary pixel adjacent to the main pixel, the auxiliary pixel including an auxiliary transistor having same characteristics as the main transistor.

In one or more embodiments, the auxiliary pixel does not include a light emitting element.

In one or more embodiments, an entire area of the auxiliary pixel is covered by a light blocking layer.

In one or more embodiments, the main transistor is electrically connected to a pixel circuit of the main pixel, and the auxiliary transistor is electrically separated from the pixel circuit of the main pixel.

In one or more embodiments, at least one of a gate, a source, or a drain of the main transistor is electrically separated from a pixel circuit of the main pixel, and at least one of a gate, a source, or a drain of the auxiliary transistor is electrically connected to the pixel circuit of the main pixel.

In one or more embodiments, the display device is further including a repair line connecting at least one of the gate, the source, or the drain of the auxiliary transistor with the pixel circuit of the main pixel.

In one or more embodiments, the display device is further including: a source connection electrode connected to the source of the main transistor; and a drain connection electrode connected to the drain of the main transistor, wherein at least one of the source connection electrode or the drain connection electrode is cut.

In one or more embodiments, the display device is further including a scan line, wherein the scan line is electrically separated from the gate of the main transistor and connected to the gate of the auxiliary transistor.

In one or more embodiments, the display device is further including a scan line, wherein the scan line is connected to the gate of the main transistor and the gate of the auxiliary transistor.

In one or more embodiments, a channel length and a channel width of the auxiliary transistor are the same as a channel length and a channel width of the main transistor.

In one or more embodiments, the display device is further including a repair line overlapping the main transistor and the auxiliary transistor.

In one or more embodiments, the display device is further including a scan line overlapping the repair line.

In one or more embodiments, the main pixel further includes a plurality of main transistors, and the auxiliary pixel further includes a plurality of auxiliary transistors, each of the plurality of auxiliary transistors having same characteristics as the plurality of main transistors.

In one or more embodiments, the auxiliary transistor and the main transistor having same characteristics have a same channel length and a same channel width.

In one or more embodiments, relative positions between the plurality of main transistors in the main pixel are same as relative positions between the plurality of auxiliary transistors in the auxiliary pixel.

In one or more embodiments, the auxiliary pixel is located at a ratio of one per n main pixels in the display device, where n is greater than or equal to 1.

In one or more embodiments, the auxiliary pixel and the n main pixels are adjacent to each other along one direction.

In one or more embodiments, the auxiliary pixel and the n main pixels are arranged along the one direction along an extension direction of a data line.

In one or more embodiments, the display device further including a repair line overlapping the auxiliary transistor of the auxiliary pixel and the main transistor of each of the n main pixels that are adjacent along the one direction.

In one or more embodiments, the light emitting element of each of the n main pixels is configured to emit light of a same color.

According to one or more embodiments of the present disclosure, an optical device including: a display device; and a light path conversion member on the display device, wherein the display device includes: a main pixel including a light emitting element, and a main transistor; and an auxiliary pixel adjacent to the main pixel, the auxiliary pixel including an auxiliary transistor having same characteristics as the main transistor.

The display device and the optical device according to the present disclosure include an auxiliary transistor of an auxiliary pixel that may replace a main transistor of a main pixel. Therefore, the transistor may be repaired by removing the main transistor determined to be defective from a pixel circuit and then connecting the auxiliary transistor to the pixel circuit.

The effects, aspects, and features of embodiments of the present disclosure are not limited to the above-described effects, aspects, and features, and other effects, aspects, and features which are not described herein will become apparent to those skilled in the art from the following description.

### BRIEF DESCRIPTION OF THE DRAWINGS

The above and other aspects and features of embodiments of the present disclosure will become more apparent by describing in detail example embodiments thereof with reference to the attached drawings, in which:

FIG. 1 is an exploded perspective view illustrating a display device according to one or more embodiments;

FIG. 2 is a layout view illustrating an example of a display panel illustrated in FIG. 1;

FIG. 3 is a block diagram illustrating the display device according to one or more embodiments;

FIG. 4 is an equivalent circuit diagram of a first pixel according to one or more embodiments;

FIG. 5 is a layout view illustrating pixels of a display area according to one or more embodiments;

FIG. 6 is a cross-sectional view illustrating an example of the display device taken along the line A-A′ of FIG. 5;

FIG. 7 is a perspective view illustrating a head mounted display device according to one or more embodiments;

FIG. 8 is an exploded perspective view illustrating an example of the head mounted display device of FIG. 7;

FIG. 9 is a perspective view illustrating a head mounted display device according to one or more embodiments;

FIG. 10 is a plan view of a display device according to one or more embodiments;

FIG. 11 is a plan view of a main pixel according to one or more embodiments;

FIG. 12 is a cross-sectional view taken along the line I-I′ of FIG. 11;

FIG. 13 is a plan view of an auxiliary pixel according to one or more embodiments;

FIG. 14 is a cross-sectional view taken along the line II-II′ of FIG. 13;

FIGS. 15, 16, 17, 18, 19, 20, and 21 are views for describing a method of repairing a first main transistor in the display device according to one or more embodiments;

FIGS. 22, 23, and 24 are views for describing a method of repairing a second main transistor in the display device according to one or more embodiments;

FIGS. 25, 26, and 27 are views for describing a method of repairing a third main transistor in the display device according to one or more embodiments; and

FIGS. 28, 29, and 30 are views for describing a method of repairing a fourth main transistor in the display device according to one or more embodiments;

FIG. 31 is a plan view of a display device according to one or more embodiments; and

FIG. 32 is a plan view of a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the present disclosure. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, one or more embodiments will be described with reference to the accompanying drawings.

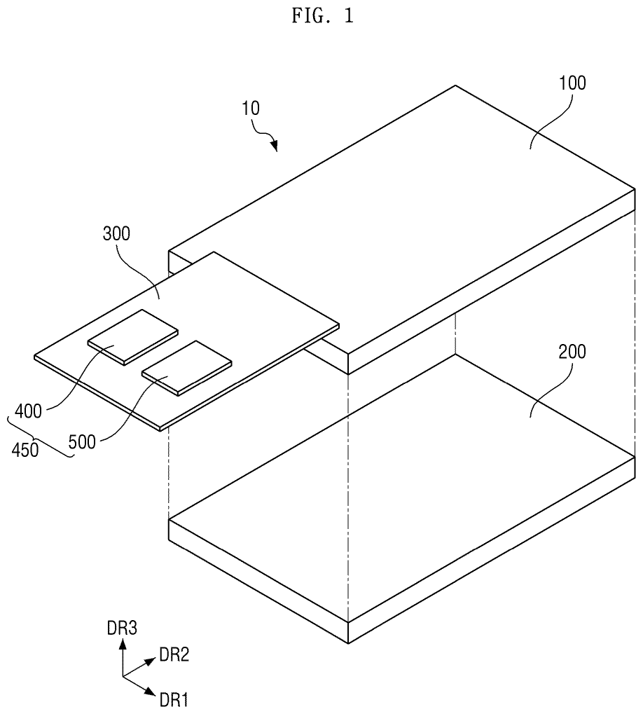

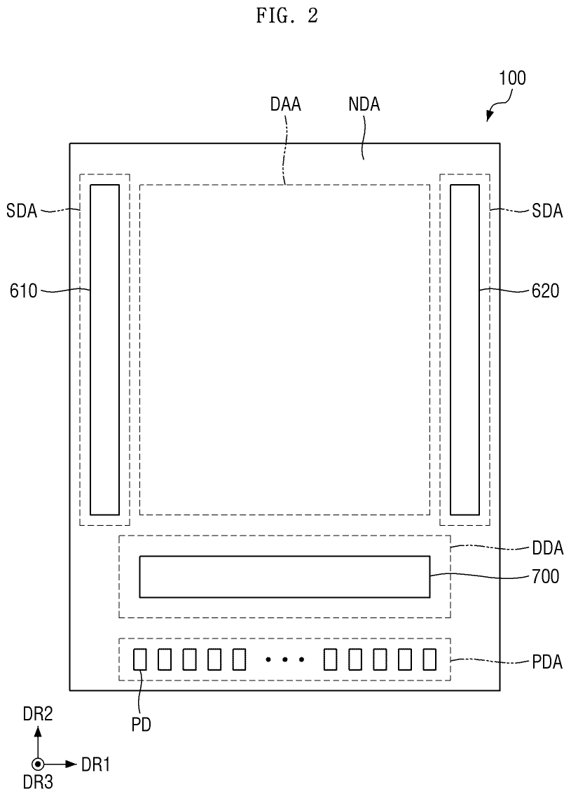

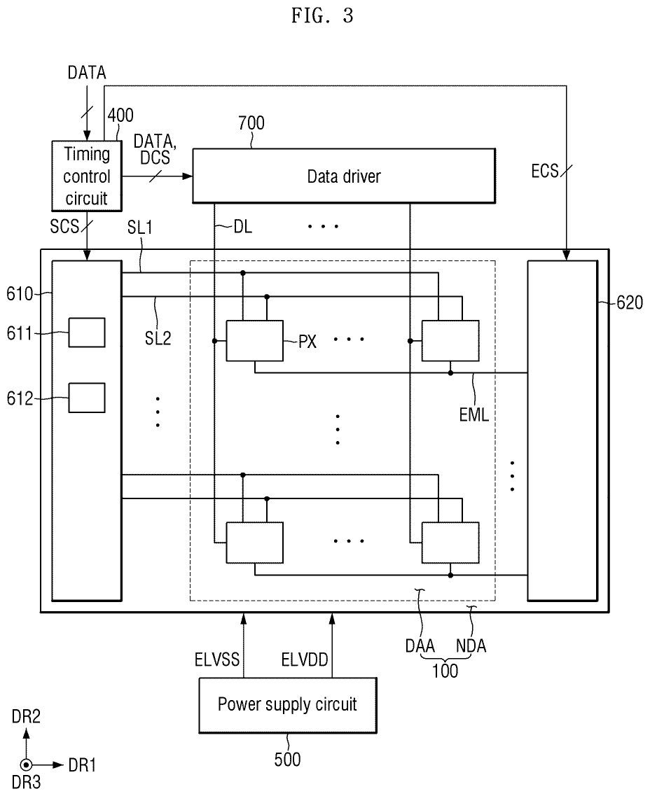

FIG. 1 is an exploded perspective view illustrating a display device according to one or more embodiments. FIG. 2 is a layout view illustrating an example of a display panel illustrated in FIG. 1. FIG. 3 is a block diagram illustrating the display device according to one or more embodiments.

Referring to FIGS. 1 and 2, a display device 10 according to one or more embodiments is a device displaying a moving image and/or a still image. The display device 10 according to one or more embodiments may be applied to portable electronic devices such as a mobile phone, a smart phone, a tablet personal computer (PC), a mobile communication terminal, an electronic notebook, an electronic book, a portable multimedia player (PMP), navigation, and an ultra-mobile PC (UMPC). For example, the display device 10 may be applied to a display unit of a television, a laptop computer, a monitor, a billboard, or the Internet of Things (IoT). Alternatively, the display device 10 may be applied to a smart watch, a watch phone, and/or a head mounted display (HMD) for implementing virtual reality and augmented reality.

The display device 10 according to one or more embodiments includes a display panel 100, a heat dissipation layer 200, a circuit board 300, and a driving circuit 450.

The display panel 100 may be formed in a planar shape similar to a quadrangle. For example, the display panel 100 may have a planar shape similar to a quadrangle having short sides in a first direction DR1 and long sides in a second direction DR2 intersecting the first direction DR1. In the display panel 100, a corner where the short side in the first direction DR1 and the long side in the second direction DR2 meet may be rounded to have a suitable curvature (e.g., a predetermined curvature) or may be formed at a right angle. The planar shape of the display panel 100 is not limited to the quadrangle, and may be formed similarly to other polygons, circles, or ovals. A planar shape of the display device 10 may follow the planar shape of the display panel 100, but the present disclosure is not limited thereto.

As illustrated in FIG. 2, the display panel 100 includes a display area DAA displaying an image and a non-display area NDA that does not display an image.

The display area DAA includes a plurality of pixels PX, a plurality of scan lines, a plurality of emission control lines, and a plurality of data lines.

Each of the plurality of pixels PX includes a light emitting element configured to emit light. The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines and the plurality of emission control lines may extend in the first direction DR1 and may be disposed in the second direction DR2. The plurality of data lines DL may extend in the second direction DR2 and may be arranged along the first direction DR1.

The plurality of scan lines includes a plurality of first scan lines and a plurality of second scan lines. The plurality of emission control lines includes a plurality of first emission control lines and a plurality of second emission control lines.

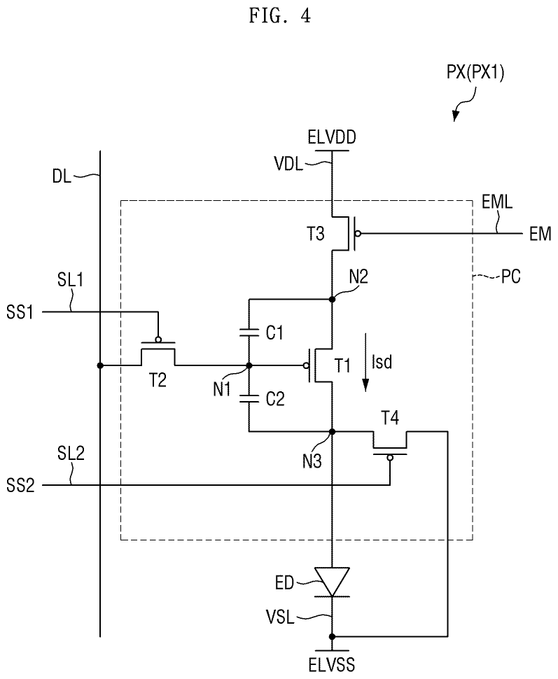

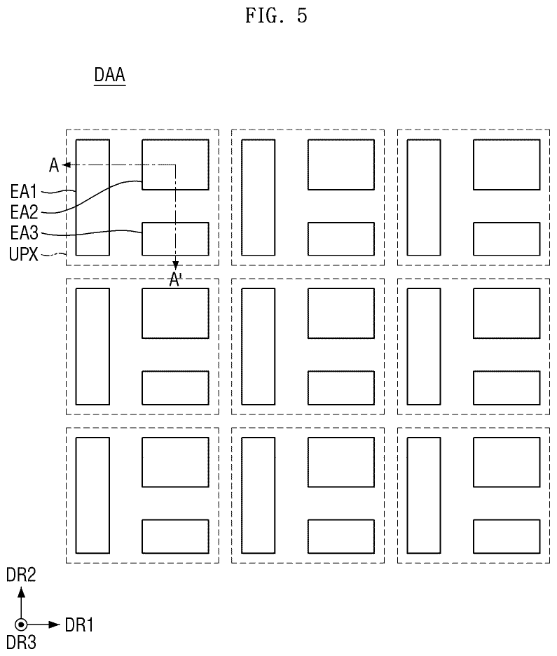

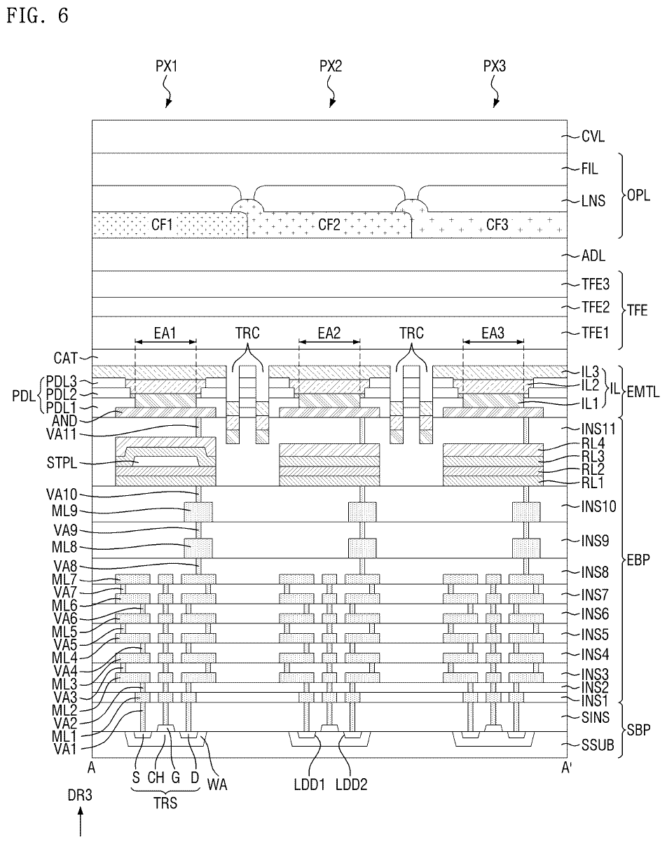

A plurality of unit pixels UPX (e.g., see FIG. 5) include a plurality of pixels PX1, PX2, and PX3. The plurality of pixels PX1, PX2, and PX3 may include a plurality of pixel transistors (e.g., T1 to T4 in FIG. 4), and the plurality of pixel transistors may be formed through a semiconductor process and may be disposed on a semiconductor substrate (e.g., SSUB in FIG. 6). For example, the plurality of pixel transistors may be formed of a complementary metal oxide semiconductor (CMOS).

Each of the plurality of pixels PX1, PX2, and PX3 may be connected to any one first scan line SL1 of the plurality of first scan lines SL1, any one second scan line SL2 of the plurality of second scan lines SL2, any one emission control line of the plurality of emission control lines EML, and any one data line DL of the plurality of data lines DL. Each of the plurality of pixels PX1, PX2, and PX3 may receive a data voltage of the data line DL according to a first scan signal of the first scan line, and may emit light from a light emitting element according to the data voltage.

The non-display area NDA may be disposed around the display area DAA along an edge or a periphery of the display area DAA and includes a scan driving area SDA, a data driving area DDA, and a pad area PDA.

The scan driving area SDA may be an area in which a scan driver 610 and an emission driver 620 are disposed. It is illustrated in FIG. 2 that the scan driver 610 is disposed on the left side of the display area DAA, and the emission driver 620 is disposed on the right side of the display area DAA, but the present disclosure is not limited thereto. For example, the scan driver 610 and the emission driver 620 may be disposed on both the left and right sides of the display area DAA.

The scan driver 610 includes a plurality of scan transistors, and the emission driver 620 includes a plurality of light emitting transistors. The plurality of scan transistors and the plurality of light emitting transistors are formed through a semiconductor process and may be formed on the semiconductor substrate described above. For example, the plurality of scan transistors and the plurality of light emitting transistors may be formed of CMOS.

The scan driver 610 may include a first scan signal output unit 611 and a second scan signal output unit 612. Each of the first scan signal output unit 611 and the second scan signal output unit 612 may receive a scan timing control signal SCS from a timing control circuit 400. The first scan signal output unit 611 may generate first scan signals according to the scan timing control signal SCS of the timing control circuit 400 and sequentially output the first scan signals to the first scan lines SL1. The second scan signal output unit 612 may generate second scan signals according to the scan timing control signal SCS and sequentially output the second scan signals to the second scan lines SL2.

The emission control driver 620 may receive an emission timing control signal ECS from the timing control circuit 400. The emission control driver 620 may generate emission control signals according to the emission timing control signal ECS and sequentially output the emission control signals to the emission control lines EML.

The data driving area DDA may be an area in which a data driver 700 is disposed. The data driver 700 may include a plurality of data transistors, and the plurality of data transistors may be formed through a semiconductor process and may be formed on the semiconductor substrate described above. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, the pixels PX1, PX2, and PX3 may be selected by the first scan signal of the scan driver 610, and the data voltages may be supplied to the selected pixels PX1, PX2, and PX3.

The pad area PDA includes a plurality of pads PD arranged along the first direction DR1. Each of the plurality of pads PD may be exposed without being covered by a cover layer (CVL in FIG. 6) and a polarizing plate.

The heat dissipation layer 200 may overlap the display panel 100 in the third direction DR3, which is a thickness direction of the display panel 100. The heat dissipation layer 200 may be disposed on one surface of the display panel 100, for example, a rear surface thereof. The heat dissipation layer 200 serves to dissipate heat generated from the display panel 100. The heat dissipation layer 200 may include a metal layer such as graphite, silver (Ag), copper (Cu), and/or aluminum (Al) having high thermal conductivity.

The circuit board 300 may be electrically connected to the plurality of pads PD of the pad area PDA of the display panel 100 by using a conductive adhesive member such as an anisotropic conductive film. The circuit board 300 may be a flexible printed circuit board (FPCB) having a flexible material, and/or a flexible film. It is illustrated in FIG. 1 that the circuit board 300 is unfolded, but the circuit board 300 may be bent. In this case, one end of the circuit board 300 may be disposed on the rear surface of the display panel 100. One end of the circuit board 300 may be an opposite end of the other end of the circuit board 300 connected to the plurality of pads PD of the pad area PDA of the display panel 100 by using a conductive adhesive member.

The driving circuit 450 may include a timing control circuit 400 and a power supply circuit 500.

The timing control circuit 400 may receive digital video data DATA and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the emission driver 620. The timing control circuit 400 may output the digital video data DATA and the data timing control signal DCS to the data driver 700.

The power supply circuit 500 may generate a plurality of panel driving voltages according to an external power voltage. For example, the power supply circuit 500 may generate a common voltage ELVSS and a driving voltage ELVDD and supply the common voltage ELVSS and the driving voltage ELVDD to the display panel 100. The common voltage ELVSS and the driving voltage ELVDD will be described later in conjunction with FIG. 4.

Each of the timing control circuit 400 and the power supply circuit 500 may be formed as an integrated circuit (IC) and attached to one surface of the circuit board 300. The scan timing control signal SCS, the emission timing control signal ECS, the digital video data DATA, and the data timing control signal DCS of the timing control circuit 400 may be supplied to the display panel 100 through the circuit board 300. The common voltage ELVSS and the driving voltage ELVDD of the power supply circuit 500 may be supplied to the display panel 100 through the circuit board 300.

FIG. 4 is an equivalent circuit diagram of a first pixel according to one or more embodiments.

As illustrated in FIG. 4, the first pixel PX1 may be connected to the first scan line SL1, the second scan line SL2, the emission control line EML, the data line DL, a driving voltage line VDL, and a common voltage line VSL. Here, the common voltage line VSL may be connected to a common electrode (e.g., a cathode electrode) of a light emitting element ED.

The pixel PX may include a pixel circuit PC and a light emitting element ED.

The pixel circuit PC may include a first transistor T1, a second transistor T2, a third transistor T3, a fourth transistor T4, a first capacitor C1, and a second capacitor C2.

The first transistor T1 (e.g., a driving transistor) may include a gate, a source, and a drain. The first transistor T1 may control a source-drain current (hereinafter, referred to as a driving current) according to a data voltage applied to the gate thereof. A driving current (e.g., Isd) flowing through a channel region of the first transistor T1 may be proportional to a square of a difference between a voltage Vsg between the source and the gate of the first transistor T1 and a threshold voltage Vth (Isd=k×(Vsg−Vth)²). Here, k is a proportional coefficient determined by a structure and physical characteristics of the first transistor T1, Vsg is a source-gate voltage of the first transistor T1, and Vth is a threshold voltage of the first transistor T1. The gate of the first transistor T1 may be electrically connected to a first node N1, the source thereof may be electrically connected to a second node N2, and the drain thereof may be electrically connected to a third node N3.

The light emitting element ED may emit light by receiving the driving current Isd. The amount of light emitted from or luminance of the light emitting element ED may be proportional to the magnitude of the driving current Isd. The light emitting element ED may be an organic light emitting diode (OLED) including a first electrode, a second electrode, and an organic light emitting layer disposed between the first electrode and the second electrode. As another example, the light emitting element ED may be an inorganic light emitting element including a first electrode, a second electrode, and an inorganic semiconductor disposed between the first electrode and the second electrode. As still another example, the light emitting element ED may be a quantum dot light emitting element including a first electrode, a second electrode, and a quantum dot light emitting layer disposed between the first electrode and the second electrode. As still another example, the light emitting element ED may be a micro light emitting diode. The first electrode of the light emitting element ED may be electrically connected to the third node N3. The second electrode of the light emitting element ED may be connected to the common voltage line VSL. The second electrode of the light emitting element ED may receive a common voltage (e.g., a low potential voltage) from the common voltage line VSL.

The second transistor T2 (e.g., a switching transistor) may be turned on by the first scan signal SS1 of the first scan line SL1 and electrically connect the data line DL and the first node N1. A gate of the second transistor T2 may be electrically connected to the first scan line SL1, a source thereof may be electrically connected to the data line DL, a drain thereof may be electrically connected to the first node N1, and a body thereof may be electrically connected to the driving voltage line VDL. Here, the data line DL may transmit a data signal DATA or a reference voltage Vref.

The third transistor T3 may be turned on by the emission control signal EM of the emission control line EML and electrically connect the driving voltage line VDL and the second node N2. A gate of the third transistor T3 may be electrically connected to the emission control line EML, a source thereof may be electrically connected to the driving voltage line VDL, and a drain thereof may be electrically connected to the second node N2.

The fourth transistor T4 may be turned on by the second scan signal SS2 of the second scan line SL2 and electrically connect the third node N3 and the common voltage line VSL. A gate of the fourth transistor T4 may be electrically connected to the second scan line SL2, a source thereof may be electrically connected to the third node N3, and a drain thereof may be electrically connected to the common voltage line VSL. In one or more embodiments, a plurality of initialization voltage lines may be provided, and the plurality of initialization voltage lines may be connected to each other. For example, the initialization voltage lines may include a plurality of horizontal initialization voltage lines extending along the first direction DR1 and arranged along the second direction DR2, and a plurality of vertical initialization voltage lines extending along the second direction DR2 and arranged along the first direction DR1. The horizontal initialization voltage lines and the vertical initialization voltage lines may be connected to each other.

The first capacitor C1 may be electrically connected between the first node N1 and the second node N2. For example, a first electrode of the first capacitor C1 may be electrically connected to the first node N1, and a second electrode of the first capacitor C1 may be electrically connected to the second node N2.

The second capacitor C2 may be electrically connected between the first node N1 and the third node N3. For example, a first electrode of the second capacitor C2 may be electrically connected to the first node N1, and a second electrode of the second capacitor C2 may be electrically connected to the third node N3.

When the first transistor T1 and the third transistor T3 are turned on, a driving current is supplied to the light emitting element ED so that the light emitting element ED may emit light.

At least one of the first to fourth transistors T1 to T4 described above may be a metal-oxide-semiconductor field effect transistor (MOSFET). For example, each of the first to fourth transistors T1 to T4 may be a P-type MOSFET. As another example, each of the first to fourth transistors T1 to T4 may be an N-type MOSFET. As still another example, some of the first to fourth transistors T1 to T4 may be P-type MOSFETs, and the remaining other transistors may be N-type MOSFETs.

It is illustrated in FIG. 4 that the first pixel PX1 includes four transistors T1 to T4 and two capacitors C1 and C2, but it should be noted that the equivalent circuit diagram of the first pixel PX1 is not limited to that illustrated in FIG. 4. For example, the number of transistors and capacitors of the first pixel PX1 is not limited to that illustrated in FIG. 4. In one or more embodiments, each of the transistors T1 to T4 may further include a body in addition to the gate, source, and drain described above, and the body of each of the transistors T1 to T4 may be connected to the driving voltage line VDL.

In addition, an equivalent circuit diagram of the second pixel PX2 and an equivalent circuit diagram of the third pixel PX3 may be substantially the same as the equivalent circuit diagram of the first pixel PX1 described with reference to FIG. 4. Therefore, descriptions of the equivalent circuit diagram of the second pixel PX2 and the equivalent circuit diagram of the third pixel PX3 are omitted in the present disclosure.

FIG. 5 is a layout view illustrating pixels of a display area according to one or more embodiments.

Referring to FIG. 5, the plurality of pixels PX may include a first light emitting area EA1, which is a light emitting area of the first pixel PX1, a second light emitting area EA2, which is a light emitting area of the second pixel PX2, and a third light emitting area EA3, which is a light emitting area of the third pixel PX3.

Each of the first light emitting area EA1, the second light emitting area EA2, and the third light emitting area EA3 may have a quadrangular planar shape such as a rectangle, a square, or a rhombus. For example, the first light emitting area EA1 may have a rectangular planar shape having a short side in the first direction DR1 and a long side in the second direction DR2. In addition, each of the second light emitting area EA2 and the third light emitting area EA3 may have a rectangular planar shape having a long side in the first direction DR1 and a short side in the second direction DR2.

A length of the first light emitting area EA1 in the first direction DR1 may be smaller than a length of the second light emitting area EA2 in the first direction DR1, and may be smaller than a length of the third light emitting area EA3 in the first direction DR1. The length of the second light emitting area EA2 in the first direction DR1 and the length of the third light emitting area EA3 in the first direction DR1 may be substantially the same.

A length of the first light emitting area EA1 in the second direction DR2 may be greater than a sum of a length of the second light emitting area EA2 in the second direction DR2 and a length of the third light emitting area EA3 in the second direction DR2. The length of the second light emitting area EA2 in the second direction DR2 may be greater than the length of the third light emitting area EA3 in the second direction DR2.

It is illustrated in FIG. 5 that each of the first light emitting area EA1, the second light emitting area EA2, and the third light emitting area EA3 has a quadrangular planar shape, but the present disclosure is not limited thereto. For example, each of the first light emitting area EA1, the second light emitting area EA2, and the third light emitting area EA3 may have a polygonal, circular, and/or elliptical planar shape other than the quadrangular shape.

In each of the plurality of pixels PX, the first light emitting area EA1 and the second light emitting area EA2 may be adjacent to each other in the first direction DR1. In addition, the first light emitting area EA1 and the third light emitting area EA3 may be adjacent to each other in the first direction DR1. In addition, the second light emitting area EA2 and the third light emitting area EA3 may be adjacent to each other in the second direction DR2. An area of the first light emitting area EA1, an area of the second light emitting area EA2, and an area of the third light emitting area EA3 may be different.

The first light emitting area EA1 may be configured to emit light of a first color, the second light emitting area EA2 may be configured to emit light of a second color, and the third light emitting area EA3 may be configured to emit light of a third color. Here, the light of the first color may be light in a blue wavelength band, the light of the second color may be light in a green wavelength band, and the light of the third color may be light in a red wavelength band. For example, the blue wavelength band may indicate that a main peak wavelength of light is included in a wavelength band of approximately 370 nm to 460 nm, the green wavelength band may indicate that a main peak wavelength of light is included in a wavelength band of approximately 480 nm to 560 nm, and the red wavelength band may indicate that a main peak wavelength of light is included in a wavelength band of approximately 600 nm to 750 nm.

It is illustrated in FIG. 5 that each of the plurality of pixels PX includes three light emitting areas EA1, EA2, and EA3, but the present disclosure is not limited thereto. That is, each of the plurality of pixels PX may also include four light emitting areas.

In addition, the arrangement of the light emitting areas of the plurality of pixels PX is not limited to that illustrated in FIG. 5. For example, the light emitting areas of the plurality of pixels PX may be disposed in a stripe structure in which the light emitting areas are arranged along the first direction DR1, a PENTILE® structure in which the light emitting areas have a diamond arrangement, or a hexagonal structure in which light emitting areas having a hexagonal planar shape are arranged. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

FIG. 6 is a cross-sectional view illustrating an example of the display device taken along the line A-A′ of FIG. 5.

Referring to FIG. 6, the display panel 100 includes a semiconductor backplane SBP, a light emitting element backplane EBP, a light emitting element layer EMTL, an encapsulation layer TFE, an optical layer OPL, a cover layer CVL, and a polarizing plate.

The semiconductor backplane SBP includes a semiconductor substrate SSUB including a plurality of pixel transistors TRS, a plurality of semiconductor insulating films covering the plurality of pixel transistors TRS, and a plurality of first vias VA1 electrically connected to the plurality of pixel transistors TRS, respectively. The plurality of pixel transistors TRS may be the first to fourth transistors T1 to T4 described with reference to FIG. 4.

The semiconductor substrate SSUB may be a silicon substrate, a germanium substrate, and/or a silicon-germanium substrate. The semiconductor substrate SSUB may be a substrate doped with first-type impurities. A plurality of well areas WA may be disposed on an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the plurality of well areas WA includes a source S corresponding to a source of the pixel transistor TRS, a drain D corresponding to a drain thereof, and a channel area CH disposed between the source S and the drain D.

Each of the source S and the drain D may be an area doped with first-type impurities. A gate G of the pixel transistor TRS may overlap the well area WA in the third direction DR3. The channel area CH may overlap the gate G in the third direction DR3. The source S may be disposed on one side of the gate G, and the drain D may be disposed on the other side of the gate G.

Each of the plurality of well areas WA further includes a first low-concentration impurity area LDD1 disposed between the channel area CH and the source S and a second low-concentration impurity area LDD2 disposed between the channel area CH and the drain D. The first low-concentration impurity area LDD1 may be an area having an impurity concentration lower than that of the source S. The second low-concentration impurity area LDD2 may be an area having an impurity concentration lower than that of the drain D. A distance between the source S and the drain D may be increased by the first low-concentration impurity area LDD1 and the second low-concentration impurity area LDD2. Therefore, because a length of the channel area CH of each of the pixel transistors TRS may increase, punch-through and hot carrier phenomena caused by a short channel may be reduced or prevented.

A semiconductor insulating film SINS may be disposed on the semiconductor substrate SSUB and the gate G of the pixel transistors TRS. The semiconductor insulating film SINS may be formed of a silicon carbon nitride (SiCN) and/or silicon oxide (SiOx)-based inorganic film, but the present disclosure is not limited thereto.

A plurality of first vias VA1 may be disposed on the pixel transistor TRS. The plurality of first vias VA1 may be connected to one of the gate G, source S, and drain D of each of the pixel transistors TRS through a hole penetrating through the semiconductor insulating film SINS. The plurality of first vias VA1 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof.

A first interlayer insulating film INS1 may be disposed on the plurality of first vias VA1.

The semiconductor substrate SSUB may be replaced with a glass substrate or a polymer resin substrate such as polyimide. In this case, thin film transistors (TFTs) may be disposed on the glass substrate or the polymer resin substrate. The glass substrate may be a rigid substrate that is not bent, and the polymer resin substrate may be a flexible substrate that may be bent and/or curved.

The light emitting element backplane EBP includes first to ninth metal layers ML1 to ML9, reflective metal layers RL1 to RL4, a plurality of vias VA1 to VA11, a plurality of interlayer insulating films INS1 to INS11, and a step layer STPL.

The first to ninth metal layers ML1 to ML9 serve to implement the circuit of the first pixel PX1 illustrated in FIG. 4 by being connected to the pixel transistor TRS of the semiconductor backplane SBP. That is, only the first to fourth transistors T1 to T4 are formed in the semiconductor backplane SBP, and the first to fourth transistors T1 to T4 and the first and second capacitors C1 and C2 are connected through the first to ninth metal layers ML1 to ML9. In addition, the drain of the first transistor T1, the source of the fourth transistor T4, and the first electrode of the light emitting element ED is also connected through the first to ninth metal layers ML1 to ML9.

A first interlayer insulating film INS1 may be disposed on the semiconductor backplane SBP. For example, the first interlayer insulating film INS1 may be disposed on the semiconductor insulating film SINS and the first vias VA1. Each of the first vias VA1 may be connected to the gate G, source S, and drain D of the pixel transistor TRS exposed by penetrating through the semiconductor insulating film SINS, respectively. Each of the first metal layers ML1 may be disposed on the semiconductor insulating film SINS and may be connected to the first via VA1.

A second interlayer insulating film INS2 may be disposed on the first interlayer insulating film INS1 and the first metal layers ML1. Each of the second vias VA2 may be connected to the first metal layer ML1 exposed by penetrating through the second interlayer insulating film INS2. Each of the second metal layers ML2 may be disposed on the second interlayer insulating film INS2 and may be connected to the second via VA2.

A third interlayer insulating film INS3 may be disposed on the second interlayer insulating film INS2 and the second metal layers ML2. Each of the third vias VA3 may be connected to the second metal layer ML2 exposed by penetrating through the third interlayer insulating film INS3. Each of the third metal layers ML3 may be disposed on the third interlayer insulating film INS3 and may be connected to the third via VA3.

A fourth interlayer insulating film INS4 may be disposed on the third interlayer insulating film INS3 and the third metal layers ML3. Each of the fourth vias VA4 may be connected to the third metal layer ML3 exposed by penetrating through the fourth interlayer insulating film INS4. Each of the fourth metal layers ML4 may be disposed on the fourth interlayer insulating film INS4 and may be connected to the fourth via VA4.

A fifth interlayer insulating film INS5 may be disposed on the fourth interlayer insulating film INS4 and the fourth metal layers ML4. Each of the fifth vias VA5 may be connected to the fourth metal layer ML4 exposed by penetrating through the fifth interlayer insulating film INS5. Each of the fifth metal layers ML5 may be disposed on the fifth interlayer insulating film INS5 and may be connected to the fifth via VA5.

A sixth interlayer insulating film INS6 may be disposed on the fifth interlayer insulating film INS5 and the fifth metal layers ML5. Each of the sixth vias VA6 may be connected to the fifth metal layer ML5 exposed by penetrating through the sixth interlayer insulating film INS6. Each of the sixth metal layers ML6 may be disposed on the sixth interlayer insulating film INS6 and may be connected to the sixth via VA6.

A seventh interlayer insulating film INS7 may be disposed on the sixth interlayer insulating film INS6 and the sixth metal layers ML6. Each of the seventh vias VA7 may be connected to the sixth metal layer ML6 exposed by penetrating through the seventh interlayer insulating film INS7. Each of the seventh metal layers ML7 may be disposed on the seventh interlayer insulating film INS7 and may be connected to the seventh via VA7.

An eighth interlayer insulating film INS8 may be disposed on the seventh interlayer insulating film INS7 and the seventh metal layers ML7. Each of the eighth vias VA8 may be connected to the seventh metal layer ML7 exposed by penetrating through the eighth interlayer insulating film INS8. Each of the eighth metal layers ML8 may be disposed on the eighth interlayer insulating film INS8 and may be connected to the eighth via VA8.

A ninth interlayer insulating film INS9 may be disposed on the eighth interlayer insulating film INS8 and the eighth metal layers ML8. Each of the ninth vias VA9 may be connected to the eighth metal layer ML8 exposed by penetrating through the ninth interlayer insulating film INS9. Each of the ninth metal layers ML9 may be disposed on the ninth interlayer insulating film INS9 and may be connected to the ninth via VA9.

The first to ninth metal layers ML1 to ML9 and the first to ninth vias VA1 to VA9 may be formed of substantially the same material. The first to ninth metal layers ML1 to ML9 and the first to ninth vias VA1 to VA9 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof. The first to ninth vias VA1 to VA9 may be formed of substantially the same material. The first to ninth interlayer insulating films INS1 to INS9 may be formed as a silicon oxide (SiOx)-based inorganic film, but the present disclosure is not limited thereto.

A thickness of the second metal layer ML2, a thickness of the third metal layer ML3, a thickness of the fourth metal layer ML4, a thickness of the fifth metal layer ML5, a thickness of the sixth metal layer ML6, and a thickness of the seventh metal layer ML7 may be greater than a thickness of the second via VA2, a thickness of the third via VA3, a thickness of the fourth via VA4, a thickness of the fifth via VA5, a thickness of the sixth via VA6, and a thickness of the seventh via VA7, respectively. Each of the thickness of the third metal layer ML3, the thickness of the fourth metal layer ML4, the thickness of the fifth metal layer ML5, the thickness of the sixth metal layer ML6, and the thickness of the seventh metal layer ML7 may be greater than the thickness of the second metal layer ML2. The thickness of the third metal layer ML3, the thickness of the fourth metal layer ML4, the thickness of the fifth 1 metal layer ML5, the thickness of the sixth metal layer ML6, and the thickness of the seventh metal layer ML7 may be substantially the same. For example, the thickness of the second metal layer ML2 may be approximately 1360 Å, each of the thickness of the third metal layer ML3, the thickness of the fourth metal layer ML4, the thickness of the fifth metal layer ML5, the thickness of the sixth metal layer ML6, and the thickness of the seventh metal layer ML7 may be approximately 1440 Å, and each of the thickness of the second via VA2, the thickness of the third via VA3, the thickness of the fourth via VA4, the thickness of the fifth via VA5, the thickness of the sixth via VA6, and the thickness of the seventh via VA7 may be 1150 Å.

Each of a thickness of the eighth metal layer ML8 and a thickness of the ninth metal layer ML9 may be greater than each of the thickness of the second metal layer ML2, the thickness of the third metal layer ML3, the thickness of the fourth metal layer ML4, the thickness of the fifth metal layer ML5, the thickness of the sixth metal layer ML6, and the thickness of the seventh metal layer ML7. Each of the thickness of the eighth metal layer ML8 and the thickness of the ninth metal layer ML9 may be greater than each of a thickness of the eighth via VA8 and a thickness of the ninth via VA9. Each of the thickness of the eighth via VA8 and the thickness of the ninth via VA9 may be greater than each of the thickness of the second via VA2, the thickness of the third via VA3, the thickness of the fourth via VA4, the thickness of the fifth via VA5, the thickness of the sixth via VA6, and the thickness of the seventh via VA7. The thickness of the eighth metal layer ML8 and the thickness of the ninth metal layer ML9 may be substantially the same. For example, each of the thickness of the eighth metal layer ML8 and the thickness of the ninth metal layer ML9 may be approximately 9000 Å. Each of the thicknesses of the eighth via VA8 and the ninth via VA9 may be approximately 6000 Å.

A tenth interlayer insulating film INS10 may be disposed on the ninth interlayer insulating film INS9 and the ninth metal layers ML9. The tenth interlayer insulating film INS10 may be formed as a silicon oxide (SiOx)-based inorganic film, but the present disclosure is not limited thereto.

Each of the tenth vias VA10 may be connected to the ninth metal layer ML9 exposed by penetrating through the tenth interlayer insulating film INS10. The tenth vias VA10 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof. A thickness of the tenth via VA10 may be approximately 16500 Å.

Each of first reflective electrodes RL1 may be disposed on the tenth interlayer insulating film INS10 and may be connected to the tenth via VA10. The first reflective electrodes RL1 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof.

Each of second reflective electrodes RL2 may be disposed on the first reflective electrode RL1. The second reflective electrodes RL2 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof. For example, the second reflective electrodes RL2 may be formed of titanium nitride (TiN).

In the first pixel PX1, a step layer STPL may be disposed on the second reflective electrode RL2. The step layer STPL may not be disposed in each of the second pixel PX2 and the third pixel PX3. A thickness of the step layer STPL may be set in consideration of a wavelength of light of a first color and a distance from a first intermediate layer IL1 to a fourth reflective electrode RL4 to be suitable in reflecting the light of the first color emitted from a first intermediate layer IL1 of the first pixel PX1. The step layer STPL may be formed of a silicon carbon nitride (SiCN) and/or silicon oxide (SiOx)-based inorganic film, but the present disclosure is not limited thereto. The thickness of the step layer STPL may be approximately 400 Å.

In the first pixel PX1, a third reflective electrode RL3 may be disposed on the second reflective electrode RL2 and the step layer STPL. In the second and third pixels PX2 and PX3, the third reflective electrode RL3 may be disposed on the second reflective electrode RL2. The third reflective electrodes RL3 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof.

At least one of the first reflective electrode RL1, the second reflective electrode RL2, and the third reflective electrode RL3 may be omitted.

Each of fourth reflective electrodes RL4 may be disposed on the third reflective electrode RL3. The fourth reflective electrodes RL4 may be layers that reflect light from first to third intermediate layers IL1, IL2, and IL3. The fourth reflective electrodes RL4 may include a metal having a high reflectance to be suitable in reflecting light. The fourth reflective electrode RL4 may be formed of aluminum (Al), a stacked structure (Ti/AI/Ti) of aluminum and titanium, a stacked structure (ITO/AI/ITO) of aluminum and ITO, an APC alloy, which is an alloy of silver (Ag), palladium (Pd), and copper (Cu), and a stacked structure (ITO/APC/ITO) of an APC alloy, and/or ITO, but the present disclosure is not limited thereto. A thickness of each of the fourth reflective electrodes RL4 may be approximately 850 Å.

An eleventh interlayer insulating film INS11 may be disposed on the tenth interlayer insulating film INS10 and the fourth reflective electrode RL4. The eleventh interlayer insulating film INS11 may be formed as a silicon oxide (SiOx)-based inorganic film, but the present disclosure is not limited thereto.

Each of the eleventh vias VA11 may be connected to the fourth reflective electrode RL4 exposed by penetrating through the eleventh interlayer insulating film INS11. The eleventh vias VA11 may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof. Due to the step layer STPL, a thickness of the eleventh via VA11 in the first pixel PX1 may be smaller than a thickness of the eleventh via VA11 in each of the second and third pixels PX2 and PX3. For example, the thickness of the eleventh via VA11 in the first pixel PX1 may be approximately 800 Å, and the thickness of the eleventh via VA11 in each of the second and third pixels PX2 and PX3 may be approximately 1200 Å.

The light emitting element layer EMTL may be disposed on the light emitting element backplane EBP. The light emitting element layer EMTL may include light emitting elements ED each including a first electrode AND, an intermediate layer IL, and a second electrode CAT, a pixel defining film PDL, and a plurality of trenches TRC.

The first electrode AND of each of the light emitting elements ED may be disposed on the eleventh interlayer insulating film INS11 and may be connected to the eleventh via VA11. The first electrode AND of each of the light emitting elements ED may be connected to the drain D or the source S of the pixel transistor TRS through the eleventh via VA11, the first to fourth reflective electrodes RL1 to RL4, the first to tenth vias VA1 to VA10, and the first to ninth metal layers ML1 to ML9. The first electrode AND of each of the light emitting elements ED may be formed of at least one of copper (Cu), aluminum (Al), tungsten (W), molybdenum (Mo), chromium (Cr), gold (Au), titanium (Ti), nickel (Ni), and/or neodymium (Nd), and/or an alloy including one or more thereof. For example, the first electrode AND of each of the light emitting elements ED may be formed of titanium nitride (TiN).

The pixel defining film PDL may be disposed on a partial area of the first electrode AND of each of the light emitting elements ED. The pixel defining film PDL may cover an edge of the first electrode AND of each of the light emitting elements ED. The pixel defining film PDL serves to partition the first light emitting areas EA1, the second light emitting areas EA2, and the third light emitting areas EA3.

The first light emitting area EA1 may be defined as an area in which the first electrode AND, the intermediate layer IL, and the second electrode CAT are sequentially stacked in the first pixel PX1 to emit light. The second light emitting area EA2 may be defined as an area in which the first electrode AND, the intermediate layer IL, and the second electrode CAT are sequentially stacked in the second pixel PX2 to emit light. The third light emitting area EA3 may be defined as an area in which the first electrode AND, the intermediate layer IL, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements ED on the eleventh interlayer insulating film INS11, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as a silicon oxide (SiOx)-based inorganic film, but the present disclosure is not limited thereto. Each of a thickness of the first pixel defining film PDL1, a thickness of the second pixel defining film PDL2, and a thickness of the third pixel defining film PDL3 may be approximately 500 Å.

Each of the plurality of trenches TRC may penetrate through the first pixel defining film PDL1, the second pixel defining film PDL2, and the third pixel defining film PDL3. In each of the plurality of trenches TRC, a portion of the eleventh interlayer insulating film INS11 may have a recessed shape.

At least one trench TRC may be disposed between the pixels PX1, PX2, and PX3 adjacent to each other. It is illustrated in FIG. 6 that two trenches TRC are disposed between the pixels PX1, PX2, and PX3 adjacent to each other, but the present disclosure is not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 emitting different light. For example, the intermediate layer may include a first intermediate layer IL1 configured to emit light of a first color, a second intermediate layer IL2 configured to emit light of a third color, and a third intermediate layer IL3 configured to emit light of a second color. The first intermediate layer IL1, the second intermediate layer IL2, and the third intermediate layer IL3 may be sequentially stacked.

The first intermediate layer IL1 may have a structure in which a first hole transporting layer, a first organic light emitting layer configured to emit light of a first color, and a first electron transporting layer are sequentially stacked. The second intermediate layer IL2 may have a structure in which a second hole transporting layer, a second organic light emitting layer configured to emit light of a third color, and a second electron transporting layer are sequentially stacked. The third intermediate layer IL3 may have a structure in which a third hole transporting layer, a third organic light emitting layer configured to emit light of a second color, and a third electron transporting layer are sequentially stacked.

A first charge generation layer for supplying charges to the second intermediate layer IL2 and supplying electrons to the first intermediate layer IL1 may be disposed between the first intermediate layer IL1 and the second intermediate layer IL2. A second charge generation layer for supplying charges to the third intermediate layer IL3 and supplying electrons to the second intermediate layer IL2 may be disposed between the second intermediate layer IL2 and the third intermediate layer IL3.

The first intermediate layer IL1 may be disposed on the first electrodes AND and the pixel defining film PDL, and may be disposed on a bottom surface of each of the trenches TRC. Due to the trench TRC, the first intermediate layer IL1 may be disconnected between the pixels PX1, PX2, and PX3 adjacent to each other. The second intermediate layer IL2 may be disposed on the first intermediate layer IL1. Due to the trench TRC, the second intermediate layer IL2 may be disconnected between the pixels PX1, PX2, and PX3 adjacent to each other. The third intermediate layer IL3 may be disposed on the second intermediate layer IL2. Due to the trench TRC, the third intermediate layer IL3 may be disconnected between the pixels PX1, PX2, and PX3 adjacent to each other. That is, each of the plurality of trenches TRC may be a structure for disconnecting the first to third intermediate layers IL1, IL2, and IL3 of the light emitting element layer EMTL between the pixels PX1, PX2, and PX3 adjacent to each other.

In order to stably disconnect the first to third intermediate layers IL1, IL2, and IL3 of the light emitting element layer EMTL between the pixels PX1, PX2, and PX3 adjacent to each other, a height of each of the plurality of trenches TRC may be greater than that of the pixel defining film PDL. The height of each of the plurality of trenches TRC indicates a length of each of the plurality of trenches TRC in the third direction DR3. The height of the pixel defining film PDL indicates a length of the pixel defining film PDL in the third direction DR3.

In order to disconnect the first to third intermediate layers IL1, IL2, and IL3 of the light emitting element layer EMTL between the pixels PX1, PX2, and PX3 adjacent to each other, other structures may be present instead of the trench TRC. For example, instead of the trench TRC, a partition wall having a reverse tapered shape may be disposed on the pixel defining film PDL.

The number of intermediate layers IL1, IL2, and IL3 that are configured to emit different lights is not limited to that illustrated in FIG. 6. For example, the intermediate layer IL may include two intermediate layers. In this case, one of the two intermediate layers may be substantially the same as the first intermediate layer IL1, and the other thereof may include a second hole transporting layer, a second organic light emitting layer, a third organic light emitting layer, and a second electron transporting layer. In this case, a charge generation layer for supplying electrons to one intermediate layer and supplying charges to the other intermediate layer may be disposed between the two intermediate layers.

In addition, it is illustrated in FIG. 6 that the first to third intermediate layers IL1, IL2, and IL3 are all disposed in the first light emitting area EA1, the second light emitting area EA2, and the third light emitting area EA3, but the present disclosure is not limited thereto. For example, the first intermediate layer IL1 may be disposed in the first light emitting area EA1 and may not be disposed in the second light emitting area EA2 and the third light emitting area EA3. In addition, the second intermediate layer IL2 may be disposed in the second light emitting area EA2 and may not be disposed in the first light emitting area EA1 and the third light emitting area EA3. In addition, the third intermediate layer IL3 may be disposed in the third light emitting area EA3 and may not be disposed in the first light emitting area EA1 and the second light emitting area EA2. In this case, first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of the plurality of trenches TRC. The second electrode CAT may be formed of a transparent conductive material (TCO) such as ITO and/or IZO capable of transmitting light, or a semi-transmissive conductive material such as magnesium (Mg), silver (Ag), and/or an alloy of magnesium (Mg) and silver (Ag). When the second electrode CAT is formed of a semi-transmissive conductive material, light emission efficiency may be increased in each of the first to third pixels PX1, PX2, and PX3 by micro cavities.

The encapsulation layer TFE may be disposed on the light emitting element layer EMTL. The encapsulation layer TFE may include one or more organic and/or inorganic films TFE1 and TFE2 to prevent oxygen or moisture from permeating into the light emitting element layer EMTL. In addition, the encapsulation layer TFE may include at least one organic film to protect the light emitting element layer EMTL from foreign substances such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be disposed on the second electrode CAT, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer (SiNx), a silicon oxynitride layer (SiON), a silicon oxide layer (SiOx), a titanium oxide layer (TiOx), and/or an aluminum oxide layer (AIOx) are alternately stacked. The encapsulation organic film TFE2 may be a monomer. In addition, the encapsulation organic film TFE2 may be an organic film made of an acrylic resin, an epoxy resin, a phenolic resin, a polyamide resin, and/or a polyimide resin.

An adhesive layer ADL may be a layer for adhering the encapsulation layer TFE and the optical layer OPL. The adhesive layer ADL may be a double-sided adhesive member. In addition, the adhesive layer ADL may be a transparent adhesive member such as a transparent adhesive and/or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may overlap the first light emitting area EA1 of the first pixel PX1. The first color filter CF1 may transmit light of a first color, that is, light in a blue wavelength band. The blue wavelength band may be approximately 370 nm to 460 nm. Therefore, the first color filter CF1 may transmit light of a first color from among light emitted from the first light emitting area EA1.

The second color filter CF2 may overlap the second light emitting area EA2 of the second pixel PX2. The second color filter CF2 may transmit light of a second color, that is, light in a green wavelength band. The green wavelength band may be approximately 480 nm to 560 nm. Therefore, the second color filter CF2 may transmit light of a second color from among light emitted from the second light emitting area EA2.

The third color filter CF3 may overlap the third light emitting area EA3 of the third pixel PX3. The third color filter CF3 may transmit light of a third color, that is, light in a red wavelength band. The red wavelength band may be approximately 600 nm to 750 nm. Therefore, the third color filter CF3 may transmit light of a third color from among light emitted from the third light emitting area EA3.

Each of the plurality of lenses LNS may be disposed on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a suitable refractive index (e.g., a predetermined refractive index) so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, and/or a polyimide resin.

The cover layer CVL may be disposed on the filling layer FIL. The cover layer CVL may be a glass substrate or a polymer resin such as resin. When the cover layer CVL is a glass substrate, the cover layer CVL may be attached onto the filling layer FIL. In this case, the filling layer FIL may serve to adhere the cover layer CVL. When the cover layer CVL is a glass substrate, the cover layer CVL may serve as an encapsulation substrate. When the cover layer CVL is a polymer resin such as resin, the cover layer CVL may be directly applied on the filling layer FIL.

The polarizing plate may be disposed on one surface of the cover layer CVL. The polarizing plate may be a structure for preventing deterioration in visibility due to reflection of external light. The polarizing plate may include a linear polarizing plate and a phase retardation film. For example, the phase retardation film may be a λ/4 (quarter-wave) plate, but the present disclosure is not limited thereto. However, when deterioration in visibility due to reflection of external light is sufficiently improved by the first to third color filters CF1, CF2, and CF3, the polarizing plate may also be omitted.

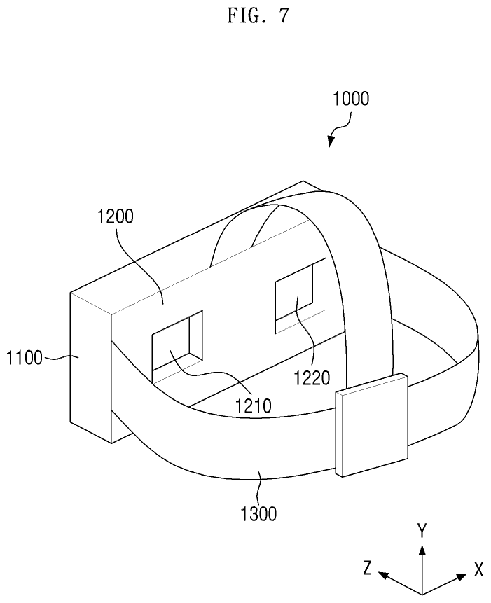

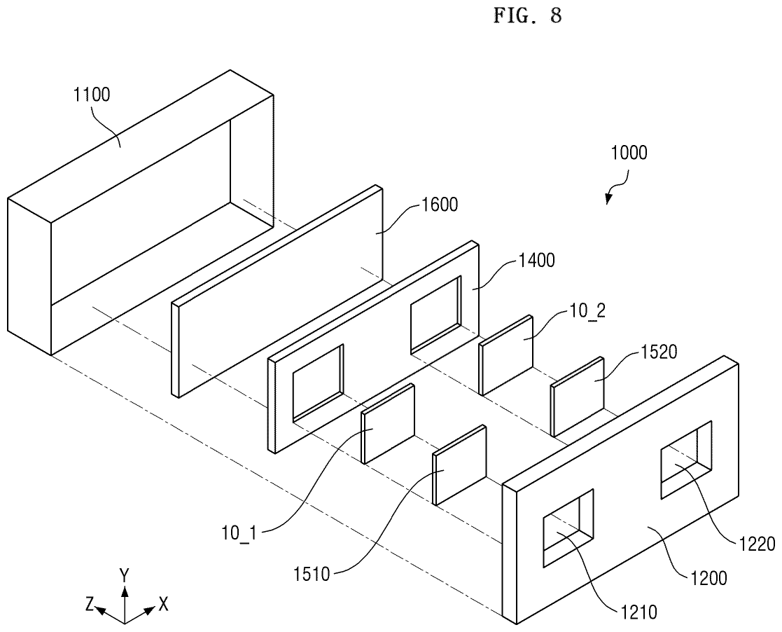

FIG. 7 is a perspective view illustrating a head mounted display device according to one or more embodiments. FIG. 8 is an exploded perspective view illustrating an example of the head mounted display device of FIG. 7.

Referring to FIGS. 7 and 8, a head mounted display device 1000 as an optical device according to one or more embodiments includes a first display device 10_1, a second display device 10_2, a display device accommodating portion 1100, an accommodating portion cover 1200, light path conversion members 1210, 1220, 1510, and 1520, a head mounting band 1300, a middle frame 1400, a control circuit board 1600, and a connector.

The light path conversion member may include a first eyepiece lens 1210, a second eyepiece lens 1220, a first optical member 1510, and a second optical member 1520.

The first display device 101 provides an image to the user's left eye, and the second display device 10_2 provides an image to the user's right eye. Because each of the first display device 10_1 and the second display device 10_2 is substantially the same as the display device 10 described with reference to FIGS. 1 to 6, descriptions of the first display device 10_1 and the second display device 10_2 are omitted.

The first optical member 1510 may be disposed between the first display device 10_1 and the first eyepiece lens 1210. The second optical member 1520 may be disposed between the second display device 10_2 and the second eyepiece lens 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device accommodating portion 1100. The control circuit board 1600 may be connected to the first display device 10_1 and the second display device 10_2 through a connector. The control circuit board 1600 may convert an image source input from the outside into digital video data DATA, and may transmit the digital video data DATA to the first display device 10_1 and the second display device 10_2 through the connector.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device accommodating portion 1100 serves to accommodate the first display device 10_1, the second display device 10_2, the middle frame 1400, the first optical member 1510, the second optical member 1520, the control circuit board 1600, and the connector. The accommodating portion cover 1200 is disposed to cover one opened surface of the display device accommodating portion 1100. The accommodating portion cover 1200 may include a first eyepiece lens 1210 where the user's left eye is disposed and a second eyepiece lens 1220 where the user's right eye is disposed. It is illustrated in FIGS. 7 and 8 that the first eyepiece lens 1210 and the second eyepiece lens 1220 are separately disposed, but the present disclosure is not limited thereto. The first eyepiece lens 1210 and the second eyepiece lens 1220 may be integrated into one.

The first eyepiece lens 1210 may be aligned with the first display device 10_1 and the first optical member 1510, and the second eyepiece lens 1220 may be aligned with the second display device 10_2 and the second optical member 1520. Therefore, the user may view an image of the first display device 10_1 magnified as a virtual image by the first optical member 1510 through the first eyepiece lens 1210, and may view an image of the second display device 10_2 magnified as a virtual image by the second optical member 1520 through the second eyepiece lens 1220.

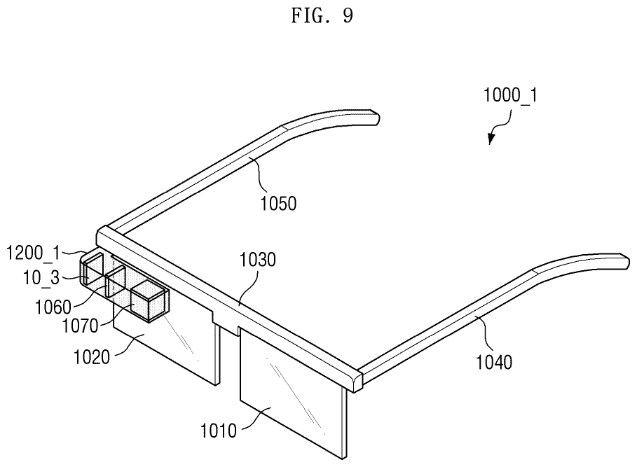

The head mounting band 1300 serves to fix the display device accommodating portion 1100 to a user's head so that the first eyepiece lens 1210 and the second eyepiece lens 1220 of the accommodating portion cover 1200 are disposed on the user's left and right eyes, respectively. When the display device accommodating portion 1100 is implemented in a lightweight and small size, the head mounted display device 1000 may include eyeglass frames as illustrated in FIG. 9 instead of the head mounting band 1300.

In addition, the head mounted display device 1000 may further include a battery for supplying power, an external memory slot for accommodating an external memory, and an external connection port and a wireless communication module for receiving an image source. The external connection port may be a universal serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 9 is a perspective view illustrating a head mounted display device according to one or more embodiments.

Referring to FIG. 9, a head mounted display device 1000_1 according to one or more embodiments may be a glasses-type display device in which a display device accommodating portion 1200_1 is implemented in a lightweight and small size. The head mounted display device 1000_1 according to one or more embodiments may include a display device 10_3, a left eye lens 1010, a right eye lens 1020, a support frame 1030, eyeglass frame legs 1040 and 1050, an optical member 1060, a light path conversion member 1070, and a display device accommodating portion 1200_1.

The display device accommodating portion 1200_1 may include the display device 10_3, the optical member 1060, and the light path conversion member 1070. As an image displayed on the display device 10_3 is magnified by the optical member 1060 and a light path thereof is converted by the light path conversion member 1070, the image may be provided to the user's right eye through the right eye lens 1020. Accordingly, the user may view an augmented reality image in which a virtual image displayed on the display device 10_3 and a real image seen through the right eye lens 1020 are combined through the right eye.

It is illustrated in FIG. 9 that the display device accommodating portion 1200_1 is disposed at a right distal end of the support frame 1030, but the present disclosure is not limited thereto. For example, the display device accommodating portion 1200_1 may be disposed at a left distal end of the support frame 1030, and in this case, the image of the display device 10_3 may be provided to the user's left eye. Alternatively, the display device accommodating portions 1200_1 may be disposed at both the left and right distal ends of the support frame 1030. In this case, the user may view the image displayed on the display device 10_3 through both the user's left and right eyes.

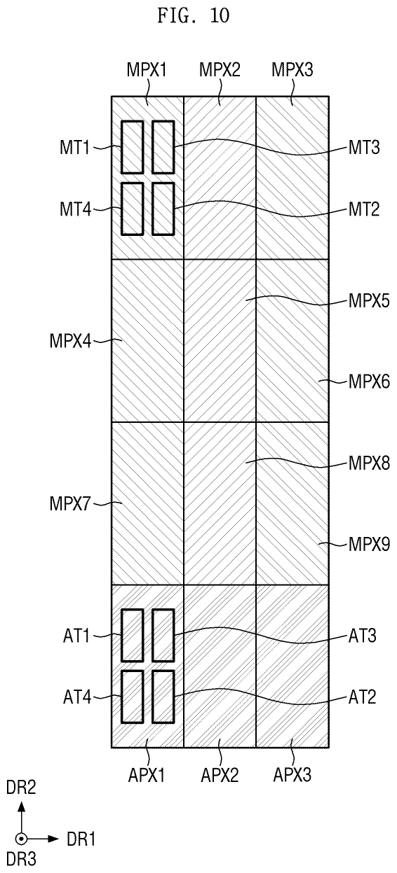

FIG. 10 is a plan view of a display device according to one or more embodiments.

As illustrated in FIG. 10, the pixel described above may be divided into a main pixel and an auxiliary pixel. For example, the main pixel may be a pixel for displaying an image, and the auxiliary pixel may be a pixel that includes a surplus transistor for replacing a defective transistor of the main pixel. Here, the auxiliary pixel may not display an image. As an example for this, the auxiliary pixel may not include the light emitting element described above.

In FIG. 10, a plurality of main pixels and a plurality of auxiliary pixels are illustrated. For example, the display device may include nine main pixels disposed three of each in first to third rows, and three auxiliary pixels disposed in a fourth row.

Three main pixels disposed to be adjacent in the same row along the first direction DR1 may provide light of different colors (or wavelengths). For example, a main pixel MPX1 in a first row and first column may be a red pixel that provides red light, a main pixel MPX2 in a first row and second column may be a green pixel that provides green light, and a main pixel MPX3 in a first row and third column may be a blue pixel that provides blue light.

Three main pixels disposed to be adjacent in the same column along the second direction DR2 may provide light of the same color (or wavelength) as each other. For example, three main pixels MPX1, MPX4, and MPX7 disposed to be adjacent to each other in the second direction DR2 along the first column may all provide the same red light.

The main pixel may include the first to fourth transistors MT1, MT2, MT3, and MT4 and the light emitting element ED as illustrated in FIG. 4. Hereinafter, for convenience of explanation, the transistor of the main pixel is defined as a main transistor.

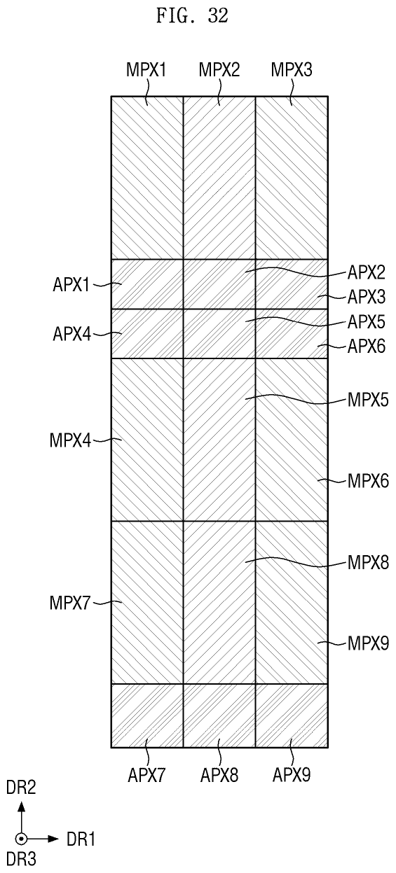

The auxiliary pixels may be disposed in the display area DAA at a ratio of one per n main pixels. Here, n may be a natural number greater than or equal to 1 (e.g., see FIG. 32). For example, as in the embodiment illustrated in FIG. 10, the auxiliary pixels may be provided in a ratio of one per three main pixels.

The main pixels and the auxiliary pixels disposed to be adjacent to each other in the second direction DR2 may form one group. The main pixel of one group may be repaired by the auxiliary pixel of any one group. For example, the three main pixels MPX1, MPX4, and MPX7 and one auxiliary pixel APX1 disposed to be adjacent in the first column along the second direction DR2 may form one group, and the three main pixels MPX1, MPX4, and MPX7 of the pixels of the one group may be repaired by one auxiliary pixel APX1 in the group.

The auxiliary pixel and n main pixels disposed to be adjacent to each other in the second direction DR2 may be disposed in one direction, for example, along an extension direction of the data line DL. In the auxiliary pixel and the n main pixels disposed to be adjacent to each other in the second direction DR2, the light emitting element ED provided in each of the n main pixels may provide light of the same color.

The auxiliary pixel may include first to fourth transistors AT1, AT2, AT3, and AT4 corresponding to the first to fourth main transistors MT1 to MT4 of the main pixel. Hereinafter, for convenience of explanation, the transistor of the auxiliary pixel is defined as an auxiliary transistor.

The first auxiliary transistor AT1 of the auxiliary pixel may be the same as the first main transistor MT1 of the main pixel. For example, the first auxiliary transistor AT1 and the first main transistor MT1 may have the same electrical characteristics. In one or more embodiments, the first auxiliary transistor AT1 and the first main transistor MT1 may have the same size (e.g., the same channel length and the same channel width).

The second auxiliary transistor AT2 of the auxiliary pixel may be the same as the second main transistor MT2 of the main pixel. For example, the second auxiliary transistor AT2 and the second main transistor MT2 may have the same electrical characteristics. In one or more embodiments, the second auxiliary transistor AT2 and the second main transistor MT2 may have the same size (e.g., the same channel length and the same channel width).

The third auxiliary transistor AT3 of the auxiliary pixel may be the same as the third main transistor MT3 of the main pixel. For example, the third auxiliary transistor AT3 and the third main transistor MT3 may have the same electrical characteristics. In one or more embodiments, the third auxiliary transistor AT3 and the third main transistor MT3 may have the same size (e.g., the same channel length and the same channel width).

The fourth auxiliary transistor AT4 of the auxiliary pixel may be the same as the fourth main transistor MT4 of the main pixel. For example, the fourth auxiliary transistor AT4 and the fourth main transistor MT4 may have the same electrical characteristics. In one or more embodiments, the fourth auxiliary transistor AT4 and the fourth main transistor MT4 may have the same size (e.g., the same channel length and the same channel width).

The auxiliary transistor of the auxiliary pixel may not be physically (and/or electrically) connected to a pixel circuit PC of the main pixel. For example, if a defective transistor does not exist in the main pixel, the auxiliary transistor may not be connected to the pixel circuit PC of the main pixel. On the other hand, the auxiliary transistor of the auxiliary pixel may be physically (and/or electrically) connected to the pixel circuit PC of the main pixel. For example, if a defective transistor exists in the main pixel, the auxiliary transistor may be connected to the pixel circuit PC of the main pixel.

The auxiliary pixels APX1, APX2, and APX3 may be covered by a light blocking layer. For example, an entire area of each of the auxiliary pixels APX1, APX2, and APX3 may be completely covered by the light blocking layer. Here, the light blocking layer may include, for example, the first pixel defining film PDL1, the second pixel defining film PDL2, and the third pixel defining film PDL3 of FIG. 6 described above. In other words, the auxiliary pixels APX1, APX2, and APX3 may overlap the first pixel defining film PDL1, the second pixel defining film PDL2, and the third pixel defining film PDL3 so as to be covered by the first pixel defining film PDL1, the second pixel defining film PDL2, and the third pixel defining film PDL3.

Relative positions between the plurality of main transistors in the main pixel may be the same as relative positions between the plurality of auxiliary transistors in the auxiliary pixel. In other words, the main transistor and auxiliary transistor having the same characteristics may be disposed in positions corresponding to each other. For example, as in the example illustrated in FIG. 10, a disposed position of the first main transistor MT1 in the first main pixel MPX1 may be the same as a disposed position of the first auxiliary transistor AT1 in the first auxiliary pixel APX1. Specifically, the first main transistor MT1 of the first main pixel MPX1 may be disposed on an upper left side of the first main pixel MPX1, and in the same manner, the first auxiliary transistor AT1 of the first auxiliary pixel APX1 may be disposed on an upper left side of the first auxiliary pixel APX1.

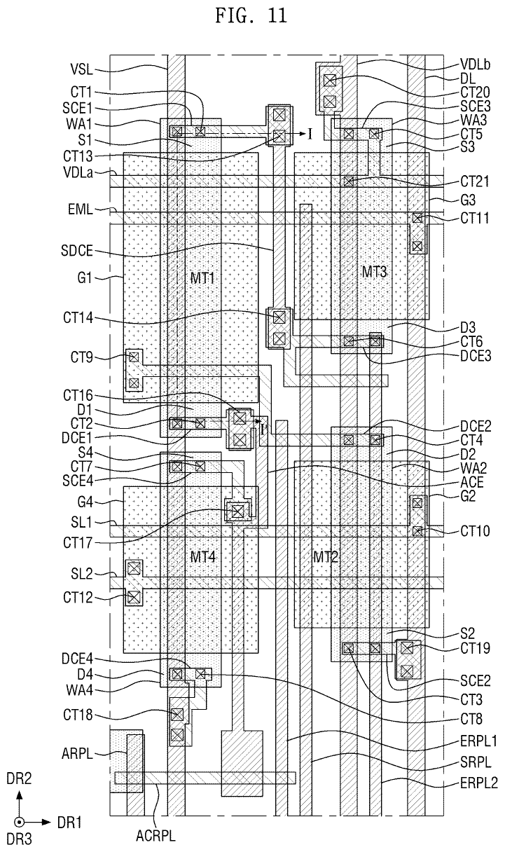

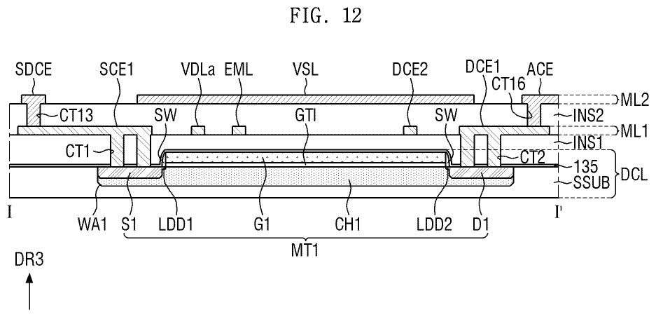

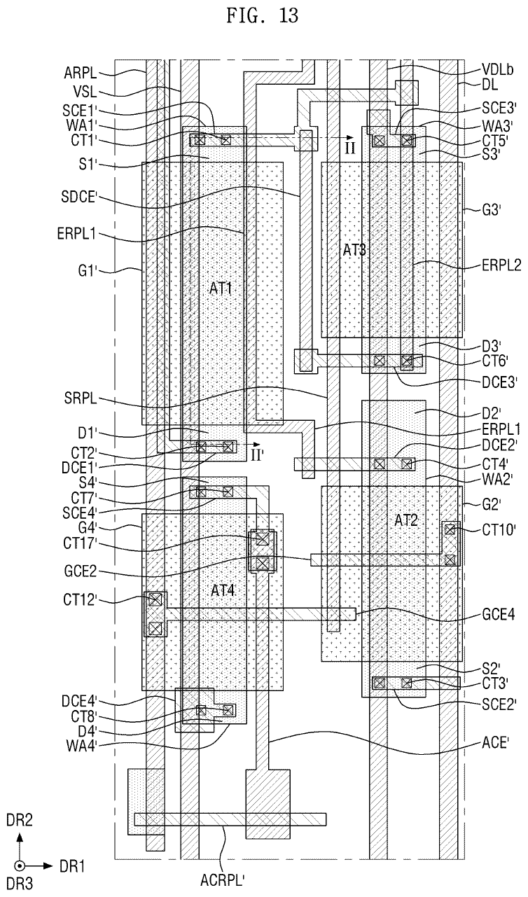

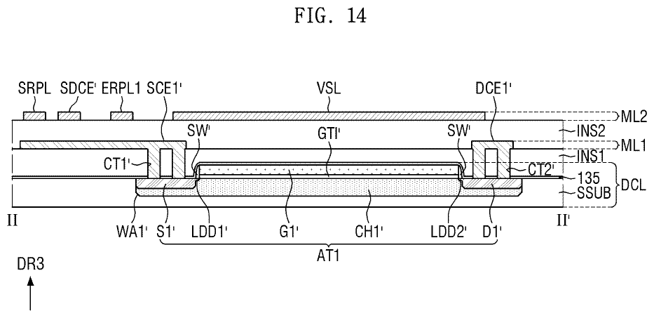

FIG. 11 is a plan view of a main pixel according to one or more embodiments, FIG. 12 is a cross-sectional view taken along the line I-I′ of FIG. 11, FIG. 13 is a plan view of an auxiliary pixel according to one or more embodiments, and FIG. 14 is a cross-sectional view taken along the line II-II′ of FIG. 13.

In one or more embodiments, the main pixel of FIG. 11 may be, for example, any one of the first main pixel MPX1, the fourth main pixel MPX4, and the seventh main pixel MPX7 of FIG. 10 described above, and the auxiliary pixel of FIG. 13 may be, for example, the first auxiliary pixel APX1 of FIG. 10 described above. In other words, the main pixel of FIG. 11 and the auxiliary pixel of FIG. 13 may be pixels disposed to be adjacent to each other along the second direction DR2 to form one group.

As illustrated in FIGS. 12 and 14, the display device may include the driving circuit layer DCL, the first interlayer insulating film INS1, the first metal layer ML1, the second interlayer insulating film INS2, and the second metal layer ML2 stacked along the third direction DR3.

As illustrated in FIGS. 11 to 14, the driving circuit layer DCL may include a substrate SSUB, gate insulating films GTI and GTI′, a protective film 135, a first main transistor MT1, a second main transistor MT2, a third main transistor MT3, a fourth main transistor MT4, a first auxiliary transistor AT1, a second auxiliary transistor AT2, a third auxiliary transistor AT3, and a fourth auxiliary transistor AT4.

As illustrated in FIG. 11, the first main transistor MT1 may include a first gate G1 overlapping a first well area WA1, a first source S1 disposed on one edge of the first well area WA1, and a first drain D1 disposed on the other edge of the first well area WA1.

As illustrated in FIG. 11, the second main transistor MT2 may include a second gate G2 overlapping a second well area WA2, a second source S2 disposed on one edge of the second well area WA2, and a second drain D2 disposed on the other edge of the second well area WA2.

As illustrated in FIG. 11, the third main transistor MT3 may include a third gate G3 overlapping a third well area WA3, a third source S3 disposed on one edge of the third well area WA3, and a third drain D3 disposed on the other edge of the third well area WA3.

As illustrated in FIG. 11, the fourth main transistor MT4 may include a fourth gate G4 overlapping a fourth well area WA4, a fourth source S4 disposed on one edge of the fourth well area WA4, and a fourth drain D4 disposed on the other edge of the fourth well area WA4.

As illustrated in FIG. 13, the first auxiliary transistor AT1 may include a first gate G1′ overlapping a first well area WA1′, a first source S1′ disposed on one edge of the first well area WA1′, and a first drain D1′ disposed on the other edge of the first well area WA1′.

As illustrated in FIG. 13, the second auxiliary transistor AT2 may include a second gate G2′ overlapping a second well area WA2′, a second source S2′ disposed on one edge of the second well area WA2′, and a second drain D2′ disposed on the other edge of the second well area WA2′.

As illustrated in FIG. 13, the third auxiliary transistor AT3 may include a third gate G3′ overlapping a third well area WA3′, a third source S3′ disposed on one edge of the third well area WA3′, and a third drain D3′ disposed on the other edge of the third well area WA3′.

As illustrated in FIG. 13, the fourth auxiliary transistor AT4 may include a fourth gate G4′ overlapping a fourth well area WA4′, a fourth source S4′ disposed on one edge of the fourth well area WA4′, and a fourth drain D4′ disposed on the other edge of the fourth well area WA4′.

When the substrate SSUB is a substrate doped with a first type impurity, each of the first well areas WA1 and WA1′, each of the second well areas WA2 and WA2′, each of the third well areas WA3 and WA3′, and each of the fourth well areas WA4 and WA4′ of the main pixel and the auxiliary pixel may each be an area doped with a second type impurity. The second type impurity may be different from the first type impurity described above. For example, when the first type impurity is a p-type impurity, the second type impurity may be an n-type impurity. In one or more embodiments, when the first type impurity is an n-type impurity, the second type impurity may be a p-type impurity.

In addition, each transistor (e.g., each main transistor and each auxiliary transistor) may further include a channel area, a low-concentration impurity area, and a sidewall. For example, as illustrated in FIG. 12, the first main transistor MT1 may further include a first channel area CH1, a first low-concentration impurity area LDD1, a second low-concentration impurity area LDD2, and a sidewall SW. As another example, as illustrated in FIG. 14, the first auxiliary transistor AT1 may further include a first channel area CH1′, a first low-concentration impurity area LDD1′, a second low-concentration impurity area LDD2′, and a sidewall SW′.

As illustrated in FIGS. 12 and 14, the first interlayer insulating film INS1 may be disposed on the driving circuit layer DCL. For example, the first interlayer insulating film INS1 may be disposed on an entire surface of the driving circuit layer DCL.

As illustrated in FIGS. 12 and 14, the first metal layer ML1 may be disposed on the first interlayer insulating film INS1.

As illustrated in FIGS. 11 and 12, the first metal layer ML1 may include a first source connection electrode SCE1, a first drain connection electrode DCE1, a second source connection electrode SCE2, a second drain connection electrode DCE2, a third source connection electrode SCE3, a third drain connection electrode DCE3, a fourth source connection electrode SCE4, a fourth drain connection electrode DCE4, and an anode connection repair line ACRPL that are disposed in the main pixel.

In addition, as illustrated in FIGS. 13 and 14, the first metal layer ML1 may include a first source connection electrode SCE1′, a first drain connection electrode DCE1′, a second source connection electrode SCE2′, a second drain connection electrode DCE2′, a third source connection electrode SCE3′, a third drain connection electrode DCE3′, a fourth source connection electrode SCE4′, a fourth drain connection electrode DCE4′, a second gate connection electrode GCE2, a fourth gate connection electrode GCE4, and an anode connection repair line ACRPL′ that are disposed in the auxiliary pixel.

In addition, as illustrated in FIGS. 11 and 12, the first metal layer ML1 may include a first scan line SL1, a second scan line SL2, an emission control line EML, and a lower driving voltage line VDLa.

The first source connection electrode SCE1 of the main pixel may be connected to the first source S1 of the first main transistor MT1 through a first contact hole CT1 penetrating through the first interlayer insulating film INS1 and the protective film 135.

The first drain connection electrode DCE1 of the main pixel may be connected to the first drain D1 of the first main transistor MT1 through a second contact hole CT2 penetrating through the first interlayer insulating film INS1 and the protective film 135.

The second source connection electrode SCE2 of the main pixel may be connected to the second source S2 of the second main transistor MT2 through a third contact hole CT3 penetrating through the first interlayer insulating film INS1 and the protective film 135.

The second drain connection electrode DCE2 of the main pixel may be connected to the second drain D2 of the second main transistor MT2 through a fourth contact hole CT4 penetrating through the first interlayer insulating film INS1 and the protective film 135. In addition, the second drain connection electrode DCE2 of the main pixel may further extend onto the first gate G1 of the first main transistor MT1 and be connected to the first gate G1 of the first main transistor MT1. For example, the second drain connection electrode DCE2 of the main pixel may be connected to the first gate G1 of the first main transistor MT1 through a ninth contact hole CT9 penetrating through the first interlayer insulating film INS1 and the protective film 135.

The third source connection electrode SCE3 of the main pixel may be connected to the third source S3 of the third main transistor MT3 through a fifth contact hole CT5 penetrating through the first interlayer insulating film INS1 and the protective film 135. In addition, the third source connection electrode SCE3 of the main pixel may further extend toward the lower driving voltage line VDLa and may be connected to the lower driving voltage line VDLa. For example, the third source connection electrode SCE3 of the main pixel and the lower driving voltage line VDLa may be integrally formed.

The third drain connection electrode DCE3 of the main pixel may be connected to the third drain D3 of the third main transistor MT3 through a sixth contact hole CT6 penetrating through the first interlayer insulating film INS1 and the protective film 135.

The fourth source connection electrode SCE4 of the main pixel may be connected to the fourth source S4 of the fourth main transistor MT4 through a seventh contact hole CT7 penetrating through the first interlayer insulating film INS1 and the protective film 135.

The fourth drain connection electrode DCE4 of the main pixel may be connected to the fourth drain D4 of the fourth main transistor MT4 through an eighth contact hole CT8 penetrating through the first interlayer insulating film INS1 and the protective film 135.

The anode connection repair line ACRPL of the main pixel may extend along the first direction DR1.

The first source connection electrode SCE1′ of the auxiliary pixel may be connected to the first source S1′ of the first auxiliary transistor AT1 through a first contact hole CT1′ penetrating through the first interlayer insulating film INS1 and the protective film 135.

The first drain connection electrode DCE1′ of the auxiliary pixel may be connected to the first drain D1′ of the first auxiliary transistor AT1 through a second contact hole CT2′ penetrating through the first interlayer insulating film INS1 and the protective film 135.

The second source connection electrode SCE2′ of the auxiliary pixel may be connected to the second source S2′ of the second auxiliary transistor AT2 through a third contact hole CT3′ penetrating through the first interlayer insulating film INS1 and the protective film 135.

The second drain connection electrode DCE2′ of the auxiliary pixel may be connected to the second drain D2′ of the second auxiliary transistor AT2 through a fourth contact hole CT4′ penetrating through the first interlayer insulating film INS1 and the protective film 135.

The third source connection electrode SCE3′ of the auxiliary pixel may be connected to the third source S3′ of the third auxiliary transistor AT3 through a fifth contact hole CT5′ penetrating through the first interlayer insulating film INS1 and the protective film 135.

The third drain connection electrode DCE3′ of the auxiliary pixel may be connected to the third drain D3′ of the third auxiliary transistor AT3 through a sixth contact hole CT6′ penetrating through the first interlayer insulating film INS1 and the protective film 135.

The fourth source connection electrode SCE4′ of the auxiliary pixel may be connected to the fourth source S4′ of the fourth auxiliary transistor AT4 through a seventh contact hole CT7′ penetrating through the first interlayer insulating film INS1 and the protective film 135.

The fourth drain connection electrode DCE4′ of the auxiliary pixel may be connected to the fourth drain D4′ of the fourth auxiliary transistor AT4 through an eighth contact hole CT8′ penetrating through the first interlayer insulating film INS1 and the protective film 135.

The second gate connection electrode GCE2 of the auxiliary pixel may be connected to the second gate G2′ of the second auxiliary transistor AT2 through a tenth contact hole CT10′ penetrating through the first interlayer insulating film INS1 and the protective film 135.

The fourth gate connection electrode GCE4 of the auxiliary pixel may be connected to the fourth gate G4′ of the fourth auxiliary transistor AT4 through a twelfth contact hole CT12′ penetrating through the first interlayer insulating film INS1 and the protective film 135.

The anode connection repair line ACRPL′ of the auxiliary pixel may extend along the first direction DR1.

The first scan line SL1 may be connected to the second gate G2 of the second main transistor MT2 through a tenth contact hole CT10 penetrating through the first interlayer insulating film INS1 and the protective film 135.

The second scan line SL2 may be connected to the fourth gate G4 of the fourth main transistor MT4 through a twelfth contact hole CT12 penetrating through the first interlayer insulating film INS1 and the protective film 135.

The emission control line EML may be connected to the third gate G3 of the third main transistor MT3 through an eleventh contact hole CT11 penetrating through the first interlayer insulating film INS1 and the protective film 135.

The lower driving voltage line VDLa may extend along the first direction DR1. The lower driving voltage line VDLa may be formed integrally with the third source connection electrode SCE3 of the main pixel described above. The lower driving voltage line VDLa may be a portion of the driving voltage line VDL described above. For example, the lower driving voltage line VDLa may include a lower driving voltage line VDLa and an upper driving voltage line VDLb, which will be described later, disposed on different layers. The lower driving voltage line VDLa and the upper driving voltage line VDLb may extend in directions intersecting each other. For example, the lower driving voltage line VDLa may extend along the first direction DR1, and the upper driving voltage line VDLb may extend along the second direction DR2. The lower driving voltage line VDLa and the upper driving voltage line VDLb may each be provided in plural. A plurality of lower driving voltage lines VDLa may be arranged along the second direction DR2, and a plurality of upper driving voltage lines VDLb may be arranged along the first direction DR1. The plurality of lower driving voltage lines VDLa and the plurality of upper driving voltage lines VDLb may be connected to each other through a twentieth contact hole CT20 and a twenty-first contact hole CT21 penetrating through the second interlayer insulating film INS2. The driving voltage line VDL including the plurality of lower driving voltage lines VDLa and the plurality of upper driving voltage lines VDLb as described above may have a mesh structure.

As illustrated in FIGS. 12 and 14, the second interlayer insulating film INS2 may be disposed on the first metal layer ML1. For example, the second interlayer insulating film INS2 may be disposed on an entire surface of the substrate SSUB including the first metal layer ML1.

As illustrated in FIGS. 11 to 14, the second metal layer ML2 may include a source-drain connection electrode SDCE and an anode connection electrode ACE disposed in the main pixel.

In addition, as illustrated in FIGS. 11 to 14, the second metal layer ML2 may include a source-drain connection electrode SDCE′ and an anode connection electrode ACE′ disposed in the auxiliary pixel.

In addition, the second metal layer ML2 may include a data line DL, an upper driving voltage line VDLb, a common voltage line VSL, a scan repair line SRPL, a first electrode repair line ERPL1, a second electrode repair line ERPL2, and an anode repair line ARPL.

The source-drain connection electrode SDCE of the main pixel may be connected to the first source connection electrode SCE1 of the main pixel through a thirteenth contact hole CT13 penetrating through the second interlayer insulating film INS2. In addition, the source-drain connection electrode SDCE of the main pixel may be connected to the third drain connection electrode DCE3 of the main pixel through a fourteenth contact hole CT14 penetrating through the second interlayer insulating film INS2.

The anode connection electrode ACE of the main pixel may be connected to the fourth source connection electrode SCE4 of the main pixel through a seventeenth contact hole CT17 penetrating through the second interlayer insulating film INS2. In addition, the anode connection electrode ACE of the main pixel may overlap the anode connection repair line ACRPL of the main pixel.

The source-drain connection electrode SDCE′ of the auxiliary pixel may overlap the first source connection electrode SCE1′ of the auxiliary pixel and the third drain connection electrode DCE3′ of the auxiliary pixel.

The anode connection electrode ACE′ of the auxiliary pixel may be connected to the fourth source connection electrode SCE4′ of the auxiliary pixel through a seventeenth contact hole CT17′ penetrating through the second interlayer insulating film INS2. In addition, the anode connection electrode ACE′ of the auxiliary pixel may overlap the anode connection repair line ACRPL′ of the auxiliary pixel.

The data line DL may be connected to the second source connection electrode SCE2 of the main pixel through a nineteenth contact hole CT19 penetrating through the second interlayer insulating film INS2. In addition, the data line DL may overlap the second source connection electrode SCE2′ of the auxiliary pixel.

The upper driving voltage line VDLb may be connected to the third source connection electrode SCE3 of the main pixel through a twentieth contact hole CT20 penetrating through the second interlayer insulating film INS2. In addition, the upper driving voltage line VDLb may overlap the third source connection electrode SCE3′ of the auxiliary pixel.

The common voltage line VSL may be connected to the fourth drain connection electrode DCE4 of the main pixel through an eighteenth contact hole CT18 penetrating through the second interlayer insulating film INS2. In addition, the common voltage line VSL may overlap the fourth drain connection electrode DCE4′ of the auxiliary pixel.

The scan repair line SRPL may extend in the second direction DR2. The scan repair line SRPL may overlap the first metal layer of the main pixel and the first metal layer of the auxiliary pixel. For example, the scan repair line SRPL may overlap the first scan line SL1, the second scan line SL2, and the emission control line EML. In addition, the scan repair line SRPL may overlap the second gate connection electrode GCE2 of the auxiliary pixel, the third gate G3′ of the third auxiliary transistor AT3, and the fourth gate connection electrode GCE4 of the auxiliary pixel. In addition, the scan repair line SRPL may overlap the second main transistor MT2 and third main transistor MT3 of the main pixel and the second auxiliary transistor AT2 and third auxiliary transistor AT3 of the auxiliary pixel.

The first electrode repair line ERPL1 may overlap the second drain connection electrode DCE2 of the main pixel, the second drain connection electrode DCE2′ of the auxiliary pixel, and the first gate G1′ of the first auxiliary transistor AT1.

The second electrode repair line ERPL2 may overlap the third drain connection electrode DCE3 of the main pixel, the first source connection electrode SCE1′ of the auxiliary pixel, and the third drain connection electrode DCE3′ of the auxiliary pixel.

The anode repair line ARPL may extend along the second direction DR2. The anode repair line ARPL may overlap the anode connection repair line ACRPL of the main pixel, the first drain connection electrode DCE1′ of the auxiliary pixel, and the anode connection repair line ACRPL′ of the auxiliary pixel.

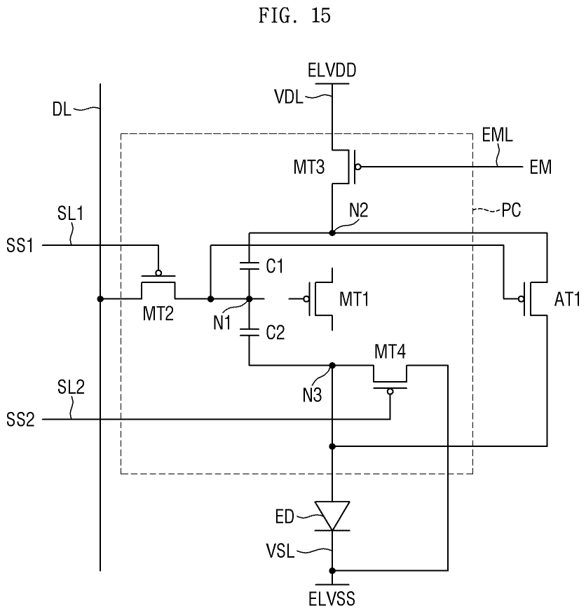

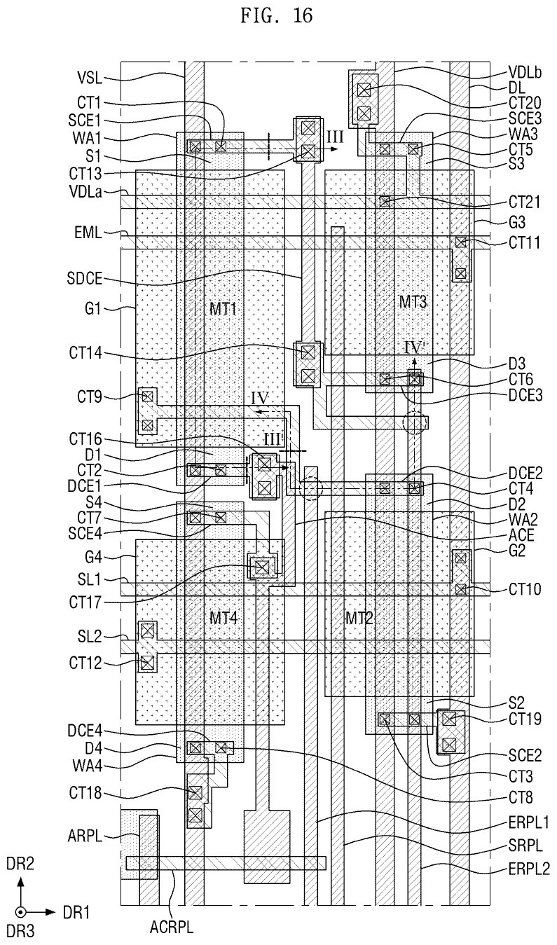

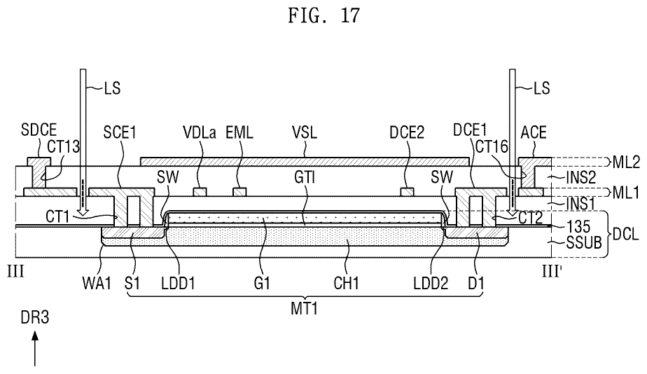

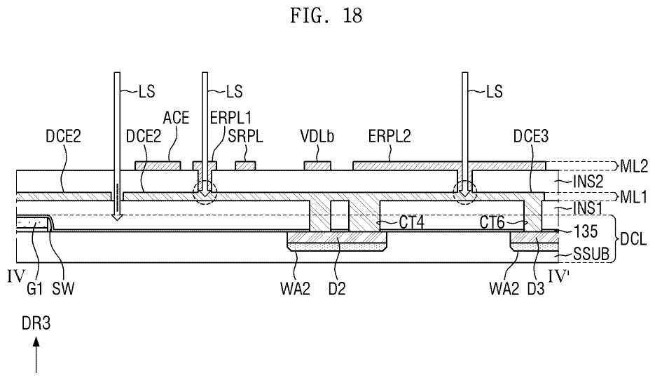

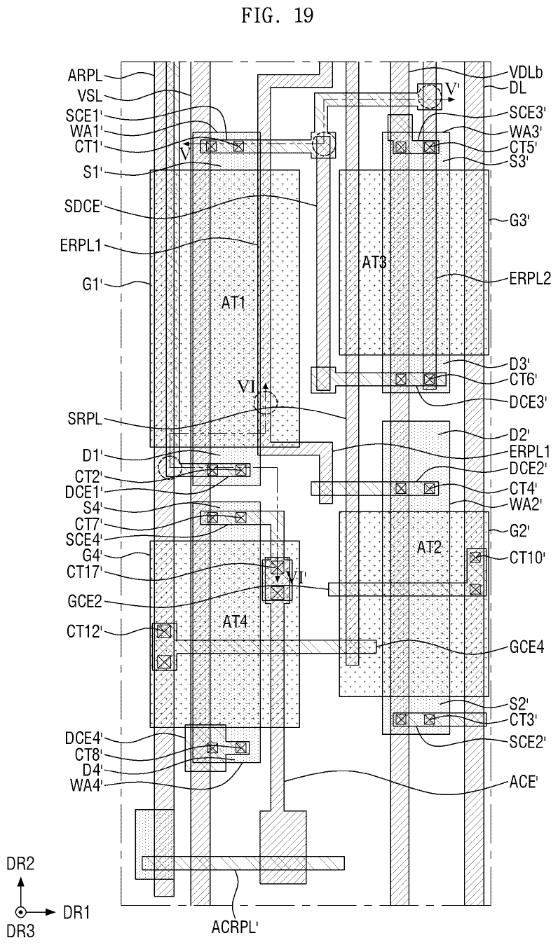

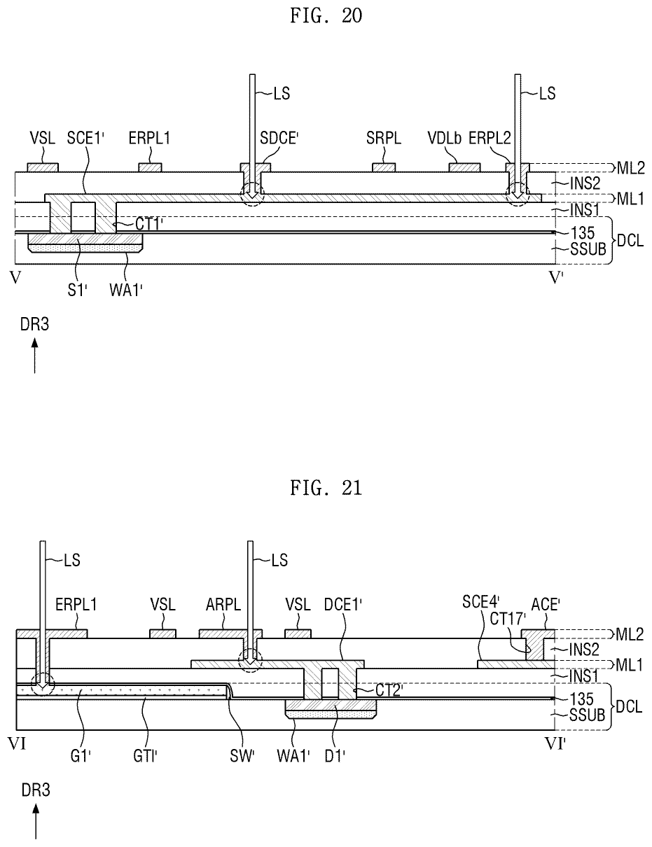

FIGS. 15, 16, 17, 18, 19, 20, and 21 are views for describing a method of repairing a first main transistor MT1 in the display device according to one or more embodiments. Here, a main pixel of FIG. 16 may correspond to the main pixel of FIG. 11 described above, and an auxiliary pixel of FIG. 19 may correspond to the auxiliary pixel of FIG. 13 described above. In addition, FIG. 17 is a cross-sectional view taken along the line III-III′ of FIG. 16, FIG. 18 is a cross-sectional view taken along the line IV-IV′ of FIG. 16, FIG. 20 is a cross-sectional view taken along the line V-V′ of FIG. 19, and FIG. 21 is a cross-sectional view taken along the line VI-VI′ in FIG. 19. In one or more embodiments, a cutting line indicated by a dotted line in FIGS. 15 to 21 means an area cut by a laser beam LS during a repair process, and an overlapping area indicated by a circular dotted line means an area connected by the laser beam LS during the repair process.

As a result of an inspection of the first main transistor MT1, when the first main transistor MT1 is determined to be defective, the first main transistor MT1 may be replaced with the first auxiliary transistor AT1 as illustrated in FIG. 15. For example, the first gate G1, the first source S1, and the first drain D1 of the first main transistor MT1 may each be electrically separated from the pixel circuit PC, and the first gate G1′, the first source S1′, and the first drain D1′ of the first auxiliary transistor AT1 may each be electrically connected to the pixel circuit PC. A method of repairing the first main transistor MT1 according to one or more embodiments for this purpose will be described in detail with reference to FIGS. 16 to 21 as follows.

First, the first main transistor MT1 may be electrically separated from the pixel circuit PC. For example, as illustrated in FIGS. 16 to 18, the second drain connection electrode DCE2 of the main pixel connected to the first gate G1 of the first main transistor MT1, the first source connection electrode SCE1 of the main pixel connected to the first source S1 of the first main transistor MT1, and the first drain connection electrode DCE1 of the main pixel connected to the first drain D1 of the first main transistor MT1 may each be cut based on the cutting lines.

In other words, a portion of the second drain connection electrode DCE2 may be cut along the cutting line so that the first gate G1 of the first main transistor MT1 may be electrically separated from the pixel circuit PC, a portion of the first source connection electrode SCE1 may be cut along the cutting line so that the first source S1 of the first main transistor MT1 may be electrically separated from the pixel circuit PC, and a portion of the first drain connection electrode DCE1 may be cut along the cutting line so that the first drain D1 of the first main transistor MT1 may be electrically separated from the pixel circuit PC. The cut second drain connection electrode DCE2, first source connection electrode SCE1, and first drain connection electrode DCE1 may each be separated into two portions based on the corresponding cutting line.

In one or more embodiments, the second drain connection electrode DCE2, the first source connection electrode SCE1, and the first drain connection electrode DCE1 may each be cut by the laser beam LS. For example, by irradiating the second drain connection electrode DCE2, the first source connection electrode SCE1, and the first drain connection electrode DCE1 with the laser beam LS along each cutting line, the second drain connection electrode DCE2, the first source connection electrode SCE1, and the first drain connection electrode DCE1 may each be separated into two portions. Accordingly, the first gate G1 of the first main transistor MT1 and the second drain D2 of the second main transistor MT2 may be electrically separated, the first source S1 of the first main transistor MT1 and the third drain D3 of the third main transistor MT3 may be electrically separated, the first drain D1 of the first main transistor MT1 and the fourth source S4 of the fourth main transistor MT4 may be electrically separated, and the first drain D1 of the first main transistor MT1 and the anode connection electrode ACE of the main pixel may be electrically separated.

Subsequently, the first auxiliary transistor AT1 may be electrically connected to the pixel circuit PC. For example, as illustrated in FIGS. 19 to 21, the first gate G1′ of the first auxiliary transistor AT1 and the first electrode repair line ERPL1 may be electrically connected to each other in an overlapping area thereof, the first source connection electrode SCE1′ connected to the first source S1′ of the first auxiliary transistor AT1 and the source-drain connection electrode SDCE′ of the auxiliary pixel may be electrically connected to each other in an overlapping area thereof, the first source connection electrode SCE1′ connected to the first source S1′ of the first auxiliary transistor AT1 and the second electrode repair line ERPL2 may be electrically connected to each other in an overlapping area thereof, and the first drain connection electrode DCE1′ connected to the first drain D1′ of the first auxiliary transistor AT1 and the anode repair line ARPL may be electrically connected to each other in an overlapping area thereof.

In one or more embodiments, by irradiating the first electrode repair line ERPL1, the source-drain connection electrode SDCE′, the second electrode repair line ERPL2, and the anode repair line ARPL with the laser beam LS in each of the overlapping areas described above, the first gate G1′ of the first auxiliary transistor AT1 and the first electrode repair line ERPL1 may be electrically connected to each other, the first source connection electrode SCE1′ of the auxiliary pixel and the source-drain connection electrode SDCE′ of the auxiliary pixel may be electrically connected to each other, the first source connection electrode SCE1′ of the auxiliary pixel and the second electrode repair line ERPL2 may be electrically connected to each other, and the first drain connection electrode DCE1′ of the auxiliary pixel and the anode repair line ARPL may be electrically connected to each other.

In addition, as illustrated in FIGS. 16 to 18, by irradiation of the laser beam LS into each overlapping area, the second drain connection electrode DCE2 of the main pixel and the first electrode repair line ERPL1 may be electrically connected to each other in an overlapping area thereof, and the third drain connection electrode DCE3 of the main pixel and the second electrode repair line ERPL2 may be electrically connected to each other in an overlapping area thereof. Here, when a portion connected to the first gate G1 of the first main transistor MT1 from among the two separated portions of the second drain connection electrode DCE2 is defined as a first portion and a portion connected to the second drain D2 of the second main transistor MT2 from among the two separated portions is defined as a second portion, the first electrode repair line ERPL1 may be connected to the second portion of the second drain connection electrode DCE2 by the irradiation of the laser beam LS described above. In other words, the first electrode repair line ERPL1 of the main pixel may be connected to the second drain D2 of the second main transistor MT2 through the second drain connection electrode DCE2 of the main pixel.

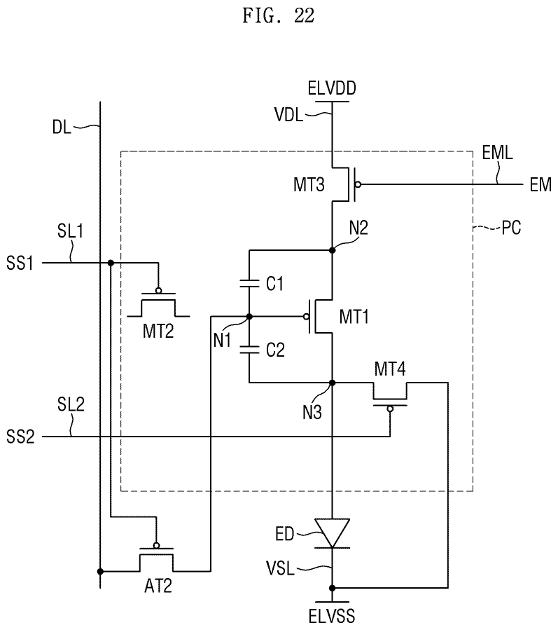

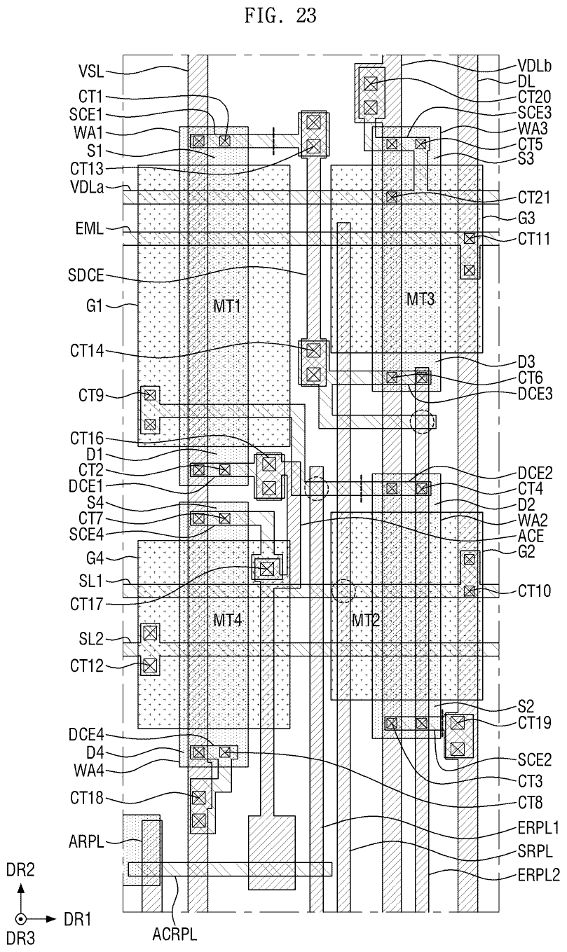

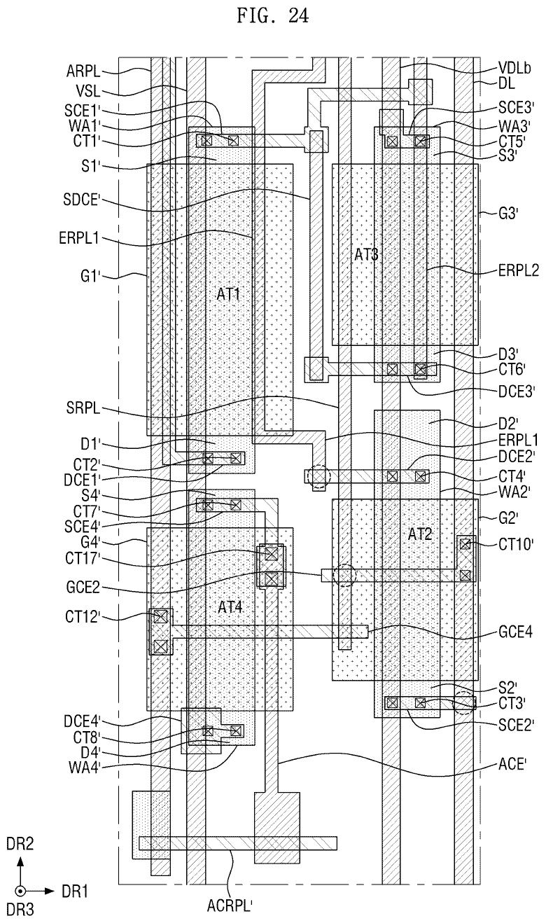

FIGS. 22, 23, and 24 are views for describing a method of repairing a second main transistor MT2 in the display device according to one or more embodiments. Here, a main pixel of FIG. 23 may correspond to the main pixel of FIG. 11 described above, and an auxiliary pixel of FIG. 24 may correspond to the auxiliary pixel of FIG. 13 described above. In one or more embodiments, a cutting line indicated by a dotted line in FIGS. 22 to 24 means an area cut by a laser beam LS during a repair process, and an overlapping area indicated by a circular dotted line means an area connected by the laser beam LS during the repair process.

As a result of an inspection of the second main transistor MT2, when the second main transistor MT2 is determined to be defective, the second main transistor MT2 may be replaced with the second auxiliary transistor AT2 as illustrated in FIG. 22. For example, the second source S2 and the second drain D2 of the second main transistor MT2 may each be electrically separated from the pixel circuit PC, and the second gate G2′, the second source S2′, and the second drain D2′ of the second auxiliary transistor AT2 may each be electrically connected to the pixel circuit PC. A method of repairing the second main transistor MT2 according to one or more embodiments for this purpose will be described in detail with reference to FIGS. 23 and 24 as follows.

First, the second main transistor MT2 may be electrically separated from the pixel circuit PC. For example, as illustrated in FIG. 23, by irradiating a laser beam LS along each cutting line, the second source connection electrode SCE2 connected to the second source S2 of the second main transistor MT2, and the second drain connection electrode DCE2 connected to the second drain D2 of the second main transistor MT2 may each be cut along the cutting line.

In other words, a portion of the second source connection electrode SCE2 may be cut along the cutting line so that the second source S2 of the second main transistor MT2 may be electrically separated from the pixel circuit PC, and a portion of the second drain connection electrode DCE2 may be cut along the cutting line so that the second drain D2 of the second main transistor MT2 may be electrically separated from the pixel circuit PC. The cut second source connection electrode SCE2 and second drain connection electrode DCE2 may each be separated into two portions based on the corresponding cutting line. Accordingly, the second source S2 of the second main transistor MT2 and the data line DL may be electrically separated, and the second drain D2 of the second main transistor MT2 and the first gate G1 of the first main transistor MT1 may be electrically separated.

Subsequently, the second auxiliary transistor AT2 may be electrically connected to the pixel circuit PC. For example, as illustrated in FIG. 24, by irradiating the laser beam LS into each overlapping area, the second gate connection electrode GCE2 of the auxiliary pixel and the scan repair line SRPL may be electrically connected to each other in an overlapping area thereof, the second source connection electrode SCE2′ of the auxiliary pixel and the data line DL may be electrically connected to each other in an overlapping area thereof, and the second drain connection electrode DCE2′ of the auxiliary pixel and the first electrode repair line ERPL1 may be electrically connected to each other in an overlapping area thereof.

In addition, as illustrated in FIG. 23, by irradiating the laser beam LS into each overlapping area, the second drain connection electrode DCE2 of the main pixel and the first electrode repair line ERPL1 may be electrically connected to each other in an overlapping area thereof, the third drain connection electrode DCE3 of the main pixel and the second electrode repair line ERPL2 may be electrically connected to each other in an overlapping area thereof, and the first scan line SL1 and the scan repair line SRPL may be electrically connected to each other in an overlapping area thereof. Here, when a portion connected to the first gate G1 of the first main transistor MT1 from among the two separated portions of the second drain connection electrode DCE2 is defined as a first portion of the second drain connection electrode DCE2 and a portion connected to the second drain D2 of the second main transistor MT2 from among the two separated portions is defined as a second portion of the second drain connection electrode DCE2, the first electrode repair line ERPL1 may be connected to the first portion of the second drain connection electrode DCE2 by the irradiation of the laser beam LS described above.

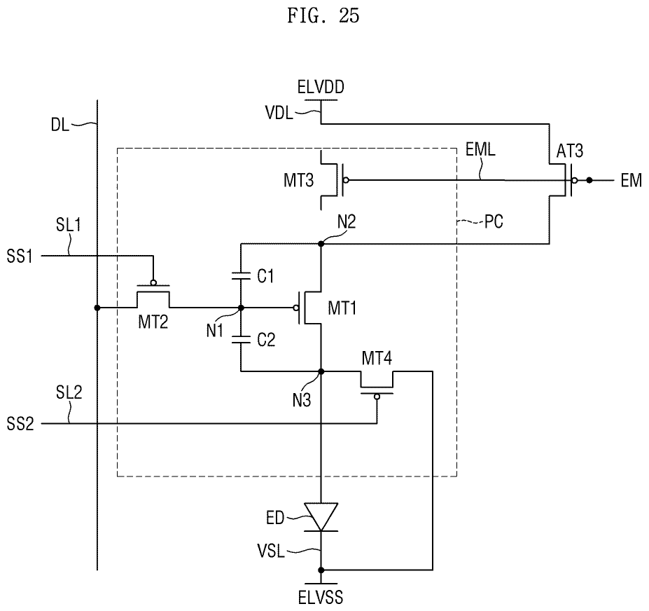

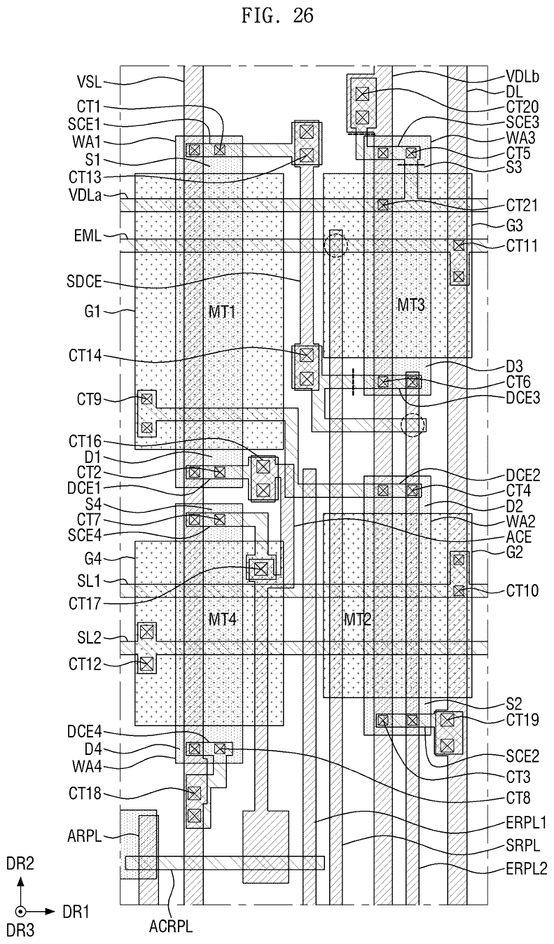

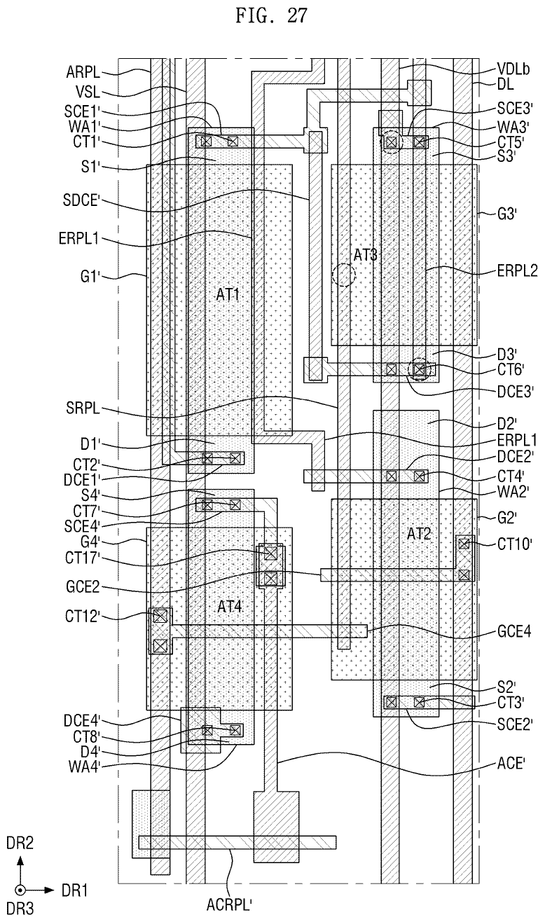

FIGS. 25, 26, and 27 are views for describing a method of repairing a third main transistor MT3 in the display device according to one or more embodiments. Here, a main pixel of FIG. 26 may correspond to the main pixel of FIG. 11 described above, and an auxiliary pixel of FIG. 27 may correspond to the auxiliary pixel of FIG. 13 described above. In one or more embodiments, a cutting line indicated by a dotted line in FIGS. 25 to 27 means an area cut by a laser beam LS during a repair process, and an overlapping area indicated by a circular dotted line means an area connected by the laser beam LS during the repair process.

As a result of an inspection of the third main transistor MT3, when the third main transistor MT3 is determined to be defective, the third main transistor MT3 may be replaced with the third auxiliary transistor AT3 as illustrated in FIG. 25. For example, the third source S3 and the third drain D3 of the third main transistor MT3 may each be electrically separated from the pixel circuit PC, and the third gate G3′, the third source S3′, and the third drain D3′ of the third auxiliary transistor AT3 may each be electrically connected to the pixel circuit PC. A method of repairing the third main transistor MT3 according to one or more embodiments for this purpose will be described in detail with reference to FIGS. 26 and 27 as follows.

First, the third main transistor MT3 may be electrically separated from the pixel circuit PC. For example, as illustrated in FIG. 26, by irradiating a laser beam LS along each cutting line, the third source connection electrode SCE3 connected to the third source S3 of the third main transistor MT3, and the third drain connection electrode DCE3 connected to the third drain D3 of the third main transistor MT3 may each be cut along the cutting line.

In other words, a portion of the third source connection electrode SCE3 may be cut along the cutting line so that the third source S3 of the third main transistor MT3 may be electrically separated from the pixel circuit PC, and a portion of the third drain connection electrode DCE3 may be cut along the cutting line so that the third drain D3 of the third main transistor MT3 may be electrically separated from the pixel circuit PC. The cut third source connection electrode SCE3 and third drain connection electrode DCE3 may each be separated into two portions based on the corresponding cutting line. Accordingly, the third source S3 of the third main transistor MT3 and the lower driving voltage line VDLa may be electrically separated, the third source S3 of the third main transistor MT3 and the upper driving voltage line VDLb may be electrically separated, and the third drain D3 of the third main transistor MT3 and the first source S1 of the first main transistor MT1 may be electrically separated.

Subsequently, the third auxiliary transistor AT3 may be electrically connected to the pixel circuit PC. For example, as illustrated in FIG. 27, by irradiating the laser beam LS into each overlapping area, the third gate G3′ of the third auxiliary transistor AT3 and the scan repair line SRPL may be electrically connected to each other in an overlapping area thereof, the third source connection electrode SCE3′ of the auxiliary pixel and the upper driving voltage line VDLb may be electrically connected to each other in an overlapping area thereof, and the third drain connection electrode DCE3′ of the auxiliary pixel and the second electrode repair line ERPL2 may be electrically connected to each other in an overlapping area thereof.

In addition, as illustrated in FIG. 26, by irradiating the laser beam LS into each overlapping area, the third drain connection electrode DCE3 of the main pixel and the second electrode repair line ERPL2 may be electrically connected to each other in an overlapping area thereof, and the emission control line EML and the scan repair line SRPL may be electrically connected to each other in an overlapping area thereof. Here, when a portion connected to the source-drain connection electrode SDCE of the main pixel from among the two separated portions of the third drain connection electrode DCE3 is defined as a first portion of the third drain connection electrode DCE3, and a portion connected to the third drain D3 of the third main transistor MT3 from among the two separated portions is defined as a second portion of the third drain connection electrode DCE3, the second electrode repair line ERPL2 may be connected to the first portion of the third drain connection electrode DCE3 by the irradiation of the laser beam LS described above.

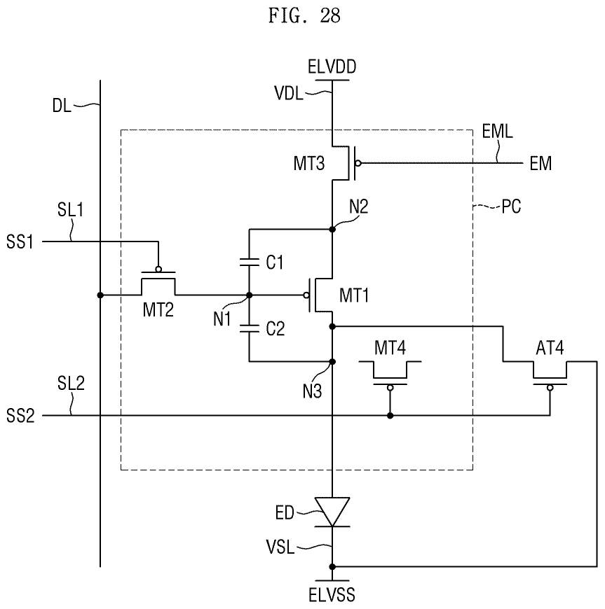

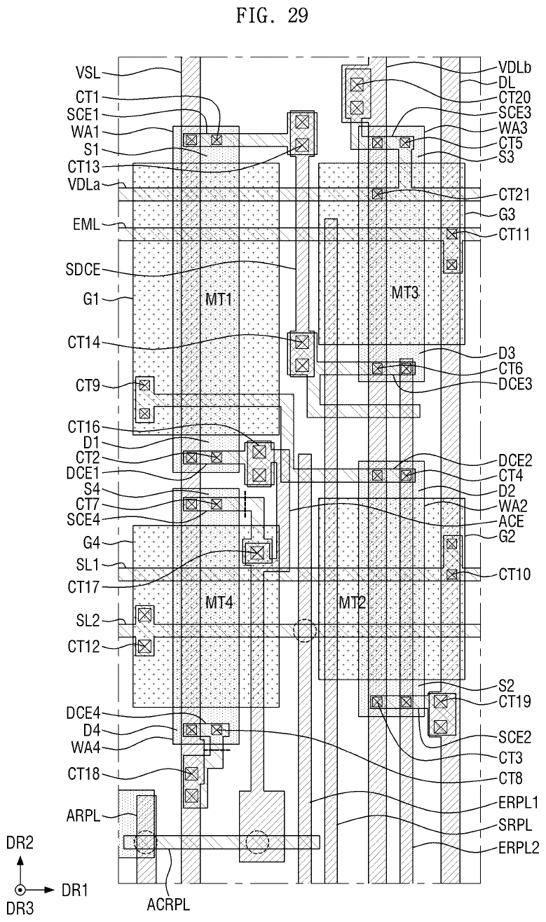

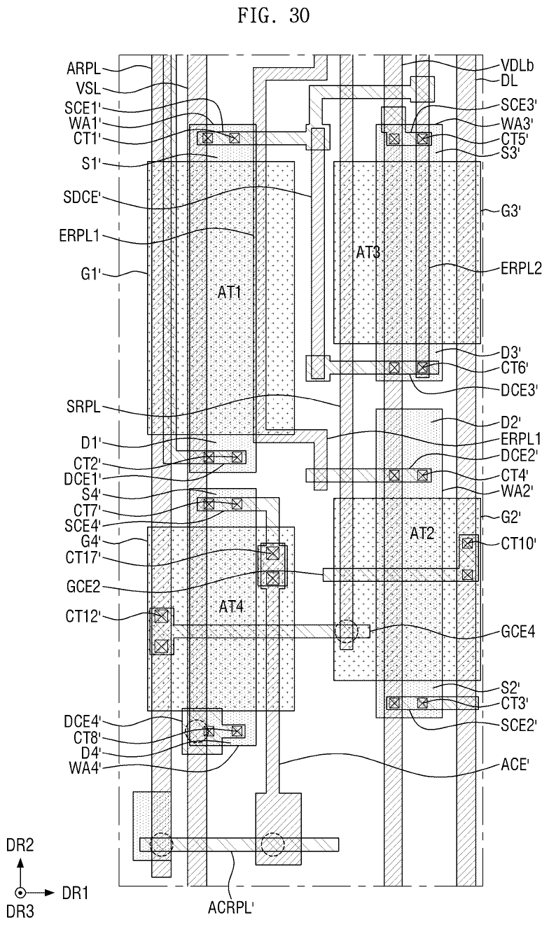

FIGS. 28, 29, and 30 are views for describing a method of repairing a fourth main transistor MT4 in the display device according to one or more embodiments. Here, a main pixel of FIG. 29 may correspond to the main pixel of FIG. 11 described above, and an auxiliary pixel of FIG. 30 may correspond to the auxiliary pixel of FIG. 13 described above. In one or more embodiments, a cutting line indicated by a dotted line in FIGS. 28 to 30 means an area cut by a laser beam LS during a repair process, and an overlapping area indicated by a circular dotted line means an area connected by the laser beam LS during the repair process.

As a result of an inspection of the fourth main transistor MT4, when the fourth main transistor MT4 is determined to be defective, the fourth main transistor MT4 may be replaced with the fourth auxiliary transistor AT4 as illustrated in FIG. 28. For example, the fourth source S4 and the fourth drain D4 of the fourth main transistor MT4 may each be electrically separated from the pixel circuit PC, and the fourth gate G4′, the fourth source S4′, and the fourth drain D4′ of the fourth auxiliary transistor AT4 may each be electrically connected to the pixel circuit PC. A method of repairing the fourth main transistor MT4 according to one or more embodiments for this purpose will be described in detail with reference to FIGS. 29 and 30 as follows.

First, the fourth main transistor MT4 may be electrically separated from the pixel circuit PC. For example, as illustrated in FIG. 29, by irradiating a laser beam LS along each cutting line, the fourth source connection electrode SCE4 connected to the fourth source S4 of the fourth main transistor MT4, and the fourth drain connection electrode DCE4 connected to the fourth drain D4 of the fourth main transistor MT4 may each be cut along the cutting line.

In other words, a portion of the fourth source connection electrode SCE4 may be cut along the cutting line so that the fourth source S4 of the fourth main transistor MT4 may be electrically separated from the pixel circuit PC, and a portion of the fourth drain connection electrode DCE4 may be cut along the cutting line so that the fourth drain D4 of the fourth main transistor MT4 may be electrically separated from the pixel circuit PC. The cut fourth source connection electrode SCE4 and fourth drain connection electrode DCE4 may each be separated into two portions based on the corresponding cutting line. Accordingly, the fourth source S4 of the fourth main transistor MT4 and the anode connection electrode ACE of the main pixel may be electrically separated, the fourth source S4 of the fourth main transistor MT4 and the first drain D1 of the first main transistor MT1 may be electrically separated, and the fourth drain D4 of the fourth main transistor MT4 and the common voltage line VSL may be electrically separated.

Subsequently, the fourth auxiliary transistor AT4 may be electrically connected to the pixel circuit PC. For example, as illustrated in FIG. 30, by irradiating the laser beam LS into each overlapping area, the fourth gate connection electrode GCE4 of the auxiliary pixel and the scan repair line SRPL may be electrically connected to each other in an overlapping area thereof, the anode connection repair line ACRPL′ of the auxiliary pixel and the anode repair line ARPL may be electrically connected to each other in an overlapping area thereof, the anode connection repair line ACRPL′ of the auxiliary pixel and the anode connection electrode ACE′ of the auxiliary pixel may be electrically connected to each other in an overlapping area thereof, and the fourth drain connection electrode DCE4′ of the auxiliary pixel and the common voltage line VSL may be electrically connected to each other in an overlapping area thereof.

In addition, as illustrated in FIG. 29, by irradiating the laser beam LS into each overlapping area, the anode connection repair line ACRPL of the main pixel and the anode repair line ARPL may be electrically connected to each other in an overlapping area thereof, the anode connection repair line ACRPL of the main pixel and the anode connection electrode ACE of the main pixel may be electrically connected to each other in an overlapping area thereof, and the second scan line SL2 and the first electrode repair line ERPL1 may be electrically connected to each other in an overlapping area thereof.

In addition, as illustrated in FIGS. 29-30, by irradiating the laser beam LS along each cutting line, the first drain connection electrode DCE1′ of the auxiliary pixel and the fourth source connection electrode SCE4′ of the auxiliary pixel may be electrically separated, and the first drain connection electrode DCE1′ of the auxiliary pixel and the anode connection electrode ACE′ of the auxiliary pixel may be electrically separated. In other words, the first drain connection electrode DCE1′ of the auxiliary pixel may be electrically separated from a connection between the fourth source connection electrode SCE4′ of the auxiliary pixel and the anode connection electrode ACE′ of the auxiliary pixel.

In one or more embodiments, whether the main transistor is defective may be determined based on a current flowing through the main transistor. As an example for this purpose, the display device 10 may include a detection unit that receives a current detected from each of the main transistors MT1 to MT4.

The detection unit may convert the current (hereinafter, sensing current) flowing through the source and drain of the corresponding main transistor into a voltage (hereinafter, sensing voltage), compare the sensing voltage with a preset determination voltage, and determine whether the main transistor is defective based on the comparison result. For example, when it is confirmed that the sensing voltage falls within a preset normal range of the determination voltage as a result of the comparison, the detection unit may determine that there is no problem in the corresponding main transistor. As a specific example, the determination voltage may have a lower limit voltage and an upper limit voltage. When the sensing voltage is equal to or greater than the lower limit voltage of the determination voltage and is equal to or less than the upper limit voltage of the determination voltage, the detection unit may determine that the corresponding main transistor is normal. On the other hand, when the sensing voltage deviates from the normal range of the determination voltage as a result of the comparison, the detection unit may determine that there is a problem in the corresponding main transistor. As a specific example, when the sensing voltage is smaller than the lower limit voltage or greater than the upper limit voltage of the determination voltage, the detection unit may determine that there is a problem in the corresponding main transistor. In other words, the detection unit may determine that the corresponding main transistor is a defective transistor.

In addition, as an example, determination of whether the main transistor is defective may be performed based on visual inspection. For example, a defect in the main transistor may be determined through an automated optical inspection (AOI) device. The AOI device may detect defects in units of micrometers (μm) using image processing algorithms and high-resolution cameras.

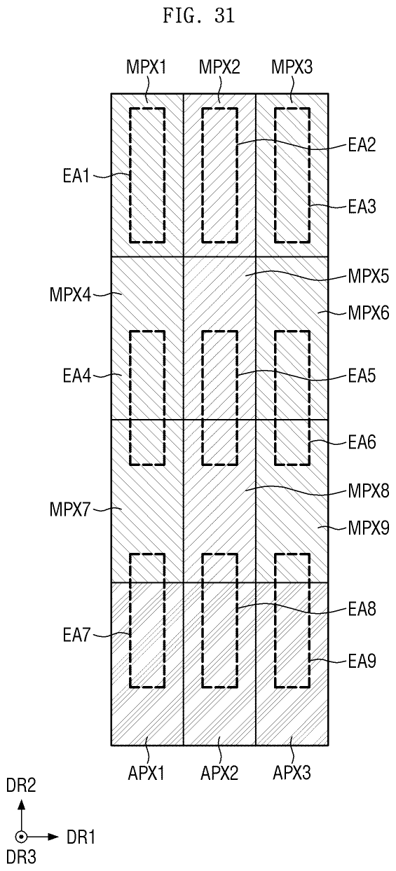

FIG. 31 is a plan view of a display device according to one or more embodiments.

FIG. 31 may be a view for describing the light emitting area of the display device of FIG. 10 described above.

As illustrated in FIG. 31, a first light emitting area EA1 of a first main pixel MPX1 may overlap the first main pixel MPX1, a second light emitting area EA2 of a second main pixel MPX2 overlaps the second main pixel MPX2, a third light emitting area EA3 of a third main pixel MPX3 may overlap the third main pixel MPX3, a fourth light emitting area EA4 of a fourth main pixel MPX4 may overlap the fourth main pixel MPX4 and a seventh main pixel MPX7, a fifth light emitting area EA5 of a fifth main pixel MPX5 may overlap the fifth main pixel MPX5 and an eighth main pixel MPX8, a sixth light emitting area EA6 of a sixth main pixel MPX6 may overlap the sixth main pixel MPX6 and a ninth main pixel MPX9, a seventh light emitting area EA7 of the seventh main pixel MPX7 may overlap the seventh main pixel MPX7 and a first auxiliary pixel APX1, an eighth light emitting area EA8 of the eighth main pixel MPX8 may overlap the eighth main pixel MPX8 and a second auxiliary pixel APX2, and a ninth light emitting area EA9 of the ninth main pixel MPX9 may overlap the ninth main pixel MPX9 and a third auxiliary pixel APX3.

First to ninth anode electrodes may be disposed in the first to ninth emission areas EA1 to EA9. In other words, the first anode electrode may overlap the first light emitting area EA1, the second anode electrode may overlap the second light emitting area EA2, the third anode electrode may overlap the third light emitting area EA3, the fourth anode electrode may overlap the fourth light emitting area EA4, the fifth anode electrode may overlap the fifth light emitting area EA5, the sixth anode electrode may overlap the sixth light emitting area EA6, the seventh anode electrode may overlap the seventh light emitting area EA7, the eighth anode electrode may overlap the eighth light emitting area EA8, and the ninth anode electrode may overlap the ninth light emitting area EA9.

The first anode electrode may correspond to a first electrode of a light emitting element provided in the first main pixel MPX1, the second anode electrode may correspond to a first electrode of a light emitting element provided in the second main pixel MPX2, the third anode electrode may correspond to a first electrode of a light emitting element provided in the third main pixel MPX3, the fourth anode electrode may correspond to a first electrode of a light emitting element provided in the fourth main pixel MPX4, the fifth anode electrode may correspond to a first electrode of a light emitting element provided in the fifth main pixel MPX5, the sixth anode electrode may correspond to a first electrode of a light emitting element provided in the sixth main pixel MPX6, the seventh anode electrode may correspond to a first electrode of a light emitting element provided in the seventh main pixel MPX7, the eighth anode electrode may correspond to a first electrode of a light emitting element provided in the eighth main pixel MPX8, and the ninth anode electrode may correspond to a first electrode of a light emitting element provided in the ninth main pixel MPX9.

The seventh anode electrode of the seventh main pixel MPX7 may overlap the seventh main pixel MPX7 and the first auxiliary pixel APX1, the eighth anode electrode of the eighth main pixel MPX8 may overlap the eighth main pixel MPX8 and the second auxiliary pixel APX2, and the ninth anode electrode of the ninth main pixel MPX9 may overlap the ninth main pixel MPX9 and the third auxiliary pixel APX3.

FIG. 32 is a plan view of a display device according to one or more embodiments.

The display device of FIG. 32 may include first to ninth main pixels MPX1 to MPX9 and first to ninth auxiliary pixels APX1 to APX9.

The first auxiliary pixel APX1 and the fourth auxiliary pixel APX4 may be disposed between the first main pixel MPX1 and the fourth main pixel MPX4, the second auxiliary pixel APX2 and the fifth auxiliary pixel APX5 may be disposed between the second main pixel MPX2 and the fifth main pixel MPX5, and the third auxiliary pixel APX3 and the sixth auxiliary pixel APX6 may be disposed between the third main pixel MPX3 and the sixth main pixel MPX6.

The first auxiliary pixel APX1 may be disposed to be adjacent to the first main pixel MPX1 in the second direction DR2, the second auxiliary pixel APX2 may be disposed to be adjacent to the second main pixel MPX2 in the second direction DR2, and the third auxiliary pixel APX3 may be disposed to be adjacent to the third main pixel MPX3 in the second direction DR2.

The fourth auxiliary pixel APX4 may be disposed to be adjacent to the fourth main pixel MPX4 in the second direction DR2, the fifth auxiliary pixel APX5 may be disposed to be adjacent to the fifth main pixel MPX5 in the second direction DR2, and the sixth auxiliary pixel APX6 may be disposed to be adjacent to the sixth main pixel MPX6 in the second direction DR2.

The fourth auxiliary pixel APX4 may be disposed between the first auxiliary pixel APX1 and the fourth main pixel MPX4, the fifth auxiliary pixel APX5 may be disposed between the second auxiliary pixel APX2 and the fifth main pixel MPX5, and the sixth auxiliary pixel APX6 may be disposed between the third auxiliary pixel APX3 and the sixth main pixel MPX6.

The seventh main pixel MPX7 may be disposed between the fourth main pixel MPX4 and the seventh auxiliary pixel APX7, the eighth main pixel MPX8 may be disposed between the fifth main pixel MPX5 and the eighth auxiliary pixel APX8, and the ninth main pixel MPX9 may be disposed between the sixth main pixel MPX6 and the ninth auxiliary pixel APX9.

The seventh auxiliary pixel APX7 may be disposed on a lower side of the seventh main pixel MPX7, the eighth auxiliary pixel APX8 may be disposed on a lower side of the eighth main pixel MPX8, and the ninth auxiliary pixel APX9 may be disposed on a lower side of the ninth main pixel MPX9.

Each of the main pixels MPX1 to MPX9 of FIG. 32 may include the first to fourth main transistors MT1 to MT4 as illustrated in FIG. 10, and each of the auxiliary pixels APX1 to APX9 of FIG. 32 may include the first to fourth auxiliary transistors AT1 to AT4 as illustrated in FIG. 10.

The main pixel and the auxiliary pixel adjacent to each other in the second direction DR2 may form one group. For example, the first main pixel MPX1 and the first auxiliary pixel APX1 may form one group, the fourth main pixel MPX4 and the fourth auxiliary pixel APX4 may form one group, and the seventh main pixel MPX7 and the seventh auxiliary pixel APX7 may form one group.

In one or more embodiments, in the same group of main pixels and auxiliary pixels, the auxiliary pixel may include at least one auxiliary transistor for repairing the main pixel. For example, the first auxiliary pixel APX1 may include at least one of the first to fourth auxiliary transistors AT1 to AT4 for repairing the first to fourth main transistors MT1 to MT4 of the first main pixel MPX1.

In one or more embodiments, each auxiliary pixel in FIG. 32 may have a smaller size than each main pixel. In this case, each auxiliary pixel in FIG. 32 may include a smaller number of transistors than each main pixel. For example, when the first main pixel MPX1 includes first to fourth main transistors MT1 to MT4, the first auxiliary pixel APX1 forming one group with the first main pixel MPX1 may include a second auxiliary transistor AT2 and a fourth auxiliary transistor AT4 corresponding to the second main transistor MT2 and the fourth main transistor MT4.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a main pixel comprising a light emitting element, and a main transistor; and
an auxiliary pixel adjacent to the main pixel, the auxiliary pixel comprising an auxiliary transistor having same characteristics as the main transistor.

2. The display device of claim 1, wherein the auxiliary pixel does not include a light emitting element.

3. The display device of claim 1, wherein an entire area of the auxiliary pixel is covered by a light blocking layer.

4. The display device of claim 1, wherein the main transistor is electrically connected to a pixel circuit of the main pixel, and
wherein the auxiliary transistor is electrically separated from the pixel circuit of the main pixel.

5. The display device of claim 1, wherein at least one of a gate, a source, or a drain of the main transistor is electrically separated from a pixel circuit of the main pixel, and
wherein at least one of a gate, a source, or a drain of the auxiliary transistor is electrically connected to the pixel circuit of the main pixel.

6. The display device of claim 5, further comprising a repair line connecting at least one of the gate, the source, or the drain of the auxiliary transistor with the pixel circuit of the main pixel.

7. The display device of claim 5, further comprising:
a source connection electrode connected to the source of the main transistor; and
a drain connection electrode connected to the drain of the main transistor,
wherein at least one of the source connection electrode or the drain connection electrode is cut.

8. The display device of claim 7, further comprising a scan line,
wherein the scan line is electrically separated from the gate of the main transistor and connected to the gate of the auxiliary transistor.

9. The display device of claim 7, further comprising a scan line,
wherein the scan line is connected to the gate of the main transistor and the gate of the auxiliary transistor.

10. The display device of claim 1, wherein a channel length and a channel width of the auxiliary transistor are the same as a channel length and a channel width of the main transistor.

11. The display device of claim 1, further comprising a repair line overlapping the main transistor and the auxiliary transistor.

12. The display device of claim 11, further comprising a scan line overlapping the repair line.

13. The display device of claim 1, wherein the main pixel further comprises a plurality of main transistors, and
wherein the auxiliary pixel further comprises a plurality of auxiliary transistors, each of the plurality of auxiliary transistors having same characteristics as the plurality of main transistors.

14. The display device of claim 13, wherein the auxiliary transistor and the main transistor having same characteristics have a same channel length and a same channel width.

15. The display device of claim 13, wherein relative positions between the plurality of main transistors in the main pixel are same as relative positions between the plurality of auxiliary transistors in the auxiliary pixel.

16. The display device of claim 1, wherein the auxiliary pixel is located at a ratio of one per n main pixels in the display device, where n is greater than or equal to 1.

17. The display device of claim 16, wherein the auxiliary pixel and the n main pixels are adjacent to each other along one direction.

18. The display device of claim 17, wherein the auxiliary pixel and the n main pixels are arranged along the one direction along an extension direction of a data line.

19. The display device of claim 17, further comprising a repair line overlapping the auxiliary transistor of the auxiliary pixel and the main transistor of each of the n main pixels that are adjacent along the one direction.

20. The display device of claim 17, wherein the light emitting element of each of the n main pixels is configured to emit light of a same color.

21. An optical device comprising:
a display device; and
a light path conversion member on the display device,
wherein the display device comprises:
a main pixel comprising a light emitting element, and a main transistor in the main pixel; and
an auxiliary pixel adjacent to the main pixel, the auxiliary pixel comprising an auxiliary transistor having same characteristics as the main transistor.
